(19) United States
(12) Patent Application Publication
(10) Pub. No.: US 2017/0062505 A1
(43) Pub. Date: Mar. 2, 2017

(54) IMAGING DEVICE AND MANUFACTURING METHOD THEREFOR

(71) Applicant: Renesas Electronics Corporation, Tokyo (JP)

(72) Inventor: Fumitoshi TAKAHASHI, Ibaraki (JP)

(73) Assignee: Renesas Electronics Corporation, Tokyo (JP)

(21) Appl. No.: 15/216,756

(22) Filed: Jul. 22, 2016

(30) Foreign Application Priority Data
Aug. 25, 2015 (JP) 2015-165708

(51) Int. Cl. H01L 27/146

(52) U.S. Cl. CPC H01L 27/14636; H01L 27/1463; H01L 27/14627; H01L 27/14621; H01L 27/14685; H01L 27/14689

(57) ABSTRACT

In an imaging device, a multilayered wiring structure is formed so as to cover a photodiode and so forth in a pixel region and a pixel transistor in a peripheral circuit region. A passivation film is formed so as to cover the multilayered wiring structure. The passivation film is interposed between a fourth interlayer insulation film and a color filter and extends from the pixel region to the peripheral circuit region in contact with the fourth interlayer insulation film. The passivation film in the peripheral circuit region is formed with a film thickness that is thicker than that of the passivation film in the pixel region.

### CROSS-REFERENCE TO RELATED APPLICATIONS

The disclosure of Japanese Patent Application No. 2015-165708 filed on Aug. 25, 2015 including the specification, drawings and abstract is incorporated herein by reference in its entirety.

### BACKGROUND

The present invention relates to an imaging device and a manufacturing method therefor and is favorably utilized in an imaging device that includes, for example, a passivation film.

In the imaging device, a pixel region and a peripheral circuit region are arranged. A pixel element that photo-electrically converts received light and outputs generated electrons as an analog signal is formed in the pixel region. A peripheral circuit element that performs correction such as removal of noises from the output analog signal and so forth, converts the analog signal so corrected into a digital signal and outputs the digital signal so converted is formed in the peripheral circuit region. Incidentally, Japanese Unexamined Patent Application Publication No. 2003-51585 is proposed as one example of a document that discloses the imaging device.

Recently, in the field of the imaging devices, refinement of processes is promoted in order to cope with a request for high quality imaging such that the number of pixels is increased and so forth. In addition, the scale of a circuit used for signal processing is increased in the peripheral circuit region with increasing the number of pixels. On the other hand, a reduction in chip size is requested to the imaging device. Therefore, it is requested to the imaging device to increase the degree of integration by increasing the number of wiring layers.

In this case, when the number of the wiring layers is increased in the pixel region similarly to an increase in number of wiring layers in the peripheral circuit region, a distance between a microlens that light is incident and a photodiode formed on a semiconductor substrate gets long, a rate that the light is attenuated until the light reaches the photodiode is increased and the sensitivity is reduced. Therefore, it is requested to reduce (promote low profile) the distance between the microlens and the photodiode by reducing the number of the wiring layers in the pixel region to a greatest possible extent.

In addition, in a semiconductor device also including the imaging device, a passivation film is formed so as to cover a semiconductor element and so forth in order to ensure humidity resistance. In the pixel region of the imaging device, a passivation film that is comparatively thin in film thickness is formed in order to suppress attenuation of light. A passivation film that is the same in film thickness as the passivation film that covers the pixel region is formed in the peripheral circuit region.

### SUMMARY

It is requested that a side face and so forth of an uppermost wiring layer be sufficiently covered with the passivation film in the peripheral circuit region of the imaging device.

However, in the peripheral circuit region of an existing imaging device, a passivation film that is the same in film thickness as the passivation film that is formed in the pixel region and is comparatively thin in film thickness is formed in order to suppress the attenuation of light. Therefore, it is anticipated that such an inconvenience will occur that it becomes difficult to sufficiently ensure the humidity resistance of the imaging device.

Other subject matters and novel features of the present invention will become apparent from the description of the present specification and the appended drawings.

An imaging device according to one embodiment of the present invention includes a semiconductor substrate, a pixel region and a peripheral circuit region, a pixel element that includes a photoelectric conversion unit, a peripheral circuit element, a multilayered wiring structure that includes a plurality of wiring layers and a plurality of interlayer insulation films, a color filter, a microlens and an interposition film. The superposition film is interposed between an uppermost insulation film that is situated at the uppermost position in the plurality of the interlayer insulation films and the color filter and extends from the pixel region to the peripheral circuit region in contact with the uppermost insulation film. In the pixel region, the interposition film is formed with a first film thickness. In the peripheral circuit region, the interposition film is formed with a second film thickness that is thicker than the first film thickness.

A manufacturing method for imaging device according to another embodiment includes the following steps. A pixel region and a peripheral circuit region are respectively defined on a semiconductor substrate. A pixel element that includes a photoelectric conversion unit is formed in the pixel region. A peripheral circuit element is formed in the peripheral circuit region. A multilayered wiring stricture that includes a plurality of wiring layers and a plurality of interlayer insulation films is formed so as to cover the pixel element and the peripheral circuit element. A color filter and a microlens are formed over an uppermost insulation film that is situated at the uppermost position in the interlayer insulation films. An interposition film that is interposed between the uppermost insulation film and the color filter and extends from the pixel region to the peripheral circuit region in contact with the uppermost insulation film is formed between the step of forming the multilayered wiring structure and the step of forming the color filter and the microlens. In the step of forming the interposition film, a first film is formed. In the first film, a part of the first film that is situated in the peripheral circuit region is left as it is, a part of the first film that is situated in the pixel region is removed and the uppermost insulation film is exposed. A second film is formed so as to cover the exposed uppermost insulation film in the pixel region and so as to cover the left part of the first film in the peripheral circuit region.

According to the imaging device relevant to one embodiment, it is possible to sufficiently ensure the humidity resistance of the imaging device.

According to the manufacturing method for imaging device relevant to another embodiment, it is possible to manufacture the imaging device that the humidity resistance is sufficiently ensured.

### BRIEF DESCRIPTION OF THE DRAWINGS

FIG. 1 is a plan view illustrating one example of a planar structure of an imaging device according to each embodiment.

FIG. 2 is a sectional diagram illustrating one example of an imaging device according to a first embodiment.

FIG. 3 is a sectional diagram illustrating examples of respective structures of a red pixel region, a green pixel region and a blue pixel region in a pixel region of the imaging device according to the first embodiment.

FIG. 4 is a sectional diagram illustrating one example of one process of a manufacturing method for the imaging device according to the first embodiment.

FIG. 5 is a sectional diagram illustrating one example of one process to be performed after the process illustrated in FIG. 4 in the first embodiment.

FIG. 6 is a sectional diagram illustrating one example of one process to be performed after the process illustrated in FIG. 5 in the first embodiment.

FIG. 7 is a sectional diagram illustrating one example of one process to be performed after the process illustrated in FIG. 6 in the first embodiment.

FIG. 8 is a sectional diagram illustrating one example of one process to be performed after the process illustrated in FIG. 7 in the first embodiment.

FIG. 9 is a sectional diagram illustrating one example of one process to be performed after the process illustrated in FIG. 8 in the first embodiment.

FIG. 10 is a sectional diagram illustrating one example of one process to be performed after the process illustrated in FIG. 9 in the first embodiment.

FIG. 11 is a sectional diagram illustrating one example of one process to be performed after the process illustrated in FIG. 10 in the first embodiment.

FIG. 12 is a sectional diagram illustrating one example of one process to be performed after the process illustrated in FIG. 11 in the first embodiment.

FIG. 13 is a sectional diagram illustrating one example of one process to be performed after the process illustrated in FIG. 12 in the first embodiment.

FIG. 14 is a sectional diagram illustrating one example of one process to be performed after the process illustrated in FIG. 13 in the first embodiment.

FIG. 15 is a sectional diagram illustrating one example of one process to be performed after the process illustrated in FIG. 14 in the first embodiment.

FIG. 16 is a sectional diagram illustrating one example of one process to be performed after the process illustrated in FIG. 15 in the first embodiment.

FIG. 17 is a sectional diagram illustrating one example of one process to be performed after the process illustrated in FIG. 16 in the first embodiment.

FIG. 18 is a sectional diagram illustrating one example of one process to be performed after the process illustrated in FIG. 17 in the first embodiment.

FIG. 19 is a sectional diagram illustrating one example of one process to be performed after the process illustrated in FIG. 18 in the first embodiment.

FIG. 20 is a sectional diagram illustrating one example of an imaging device according to a comparative example.

FIG. 21 is a sectional diagram illustrating one example of one process of a manufacturing method for an imaging device according to a second embodiment.

FIG. 22 is a sectional diagram illustrating one example of one process to be performed after the process illustrated in FIG. 21 in the second embodiment.

FIG. 23 is a sectional diagram illustrating one example of one process to be performed after the process illustrated in FIG. 22 in the second embodiment.

FIG. 24 is a sectional diagram illustrating one example of one process to be performed after the process illustrated in FIG. 23 in the second embodiment, the sectional diagram of the imaging device that formation of principal parts has been completed.

FIG. 25 is a sectional diagram illustrating one example of one process of a manufacturing method for an imaging device according to a third embodiment.

FIG. 26 is a sectional diagram illustrating one example of one process to be performed after the process illustrated in FIG. 25 in the third embodiment.

FIG. 27 is a sectional diagram illustrating one example of one process to be performed after the process illustrated in FIG. 26 in the third embodiment, the sectional diagram of the imaging device that formation of the principal parts has been completed.

FIG. 28 is a sectional diagram illustrating one example of one process of a manufacturing method for an imaging device according to a fourth embodiment.

FIG. 29 is a sectional diagram illustrating one example of one process to be performed after the process illustrated in FIG. 28 in the fourth embodiment.

FIG. 30 is a sectional diagram illustrating one example of one process to be performed after the process illustrated in FIG. 29 in the fourth embodiment.

FIG. 31 is a sectional diagram illustrating one example of one process to be performed after the process illustrated in FIG. 30 in the fourth embodiment.

FIG. 32 is a sectional diagram illustrating one example of one process to be performed after the process illustrated in FIG. 31 in the fourth embodiment.

FIG. 33 is a sectional diagram illustrating one example of one process to be performed after the process illustrated in FIG. 32 in the fourth embodiment, the sectional diagram of the imaging device that formation of the principal parts has been completed.

FIG. 34 is a sectional diagram illustrating one example of one process of a manufacturing method for an imaging device according to a fifth embodiment.

FIG. 35 is a sectional diagram illustrating one example of one process to be performed after the process illustrated in FIG. 34 in the fifth embodiment.

FIG. 36 is a sectional diagram illustrating one example of one process to be performed after the process illustrated in FIG. 35 in the fifth embodiment, the sectional diagram of the imaging device that formation of the principal parts has been completed.

FIG. 37 is a sectional diagram illustrating one example of one process of a manufacturing method for an imaging device according to a sixth embodiment.

FIG. 38 is a sectional diagram illustrating one example of one process to be performed after the process illustrated in FIG. 37 in the sixth embodiment.

FIG. 39 is a sectional diagram illustrating one example of one process to be performed after the process illustrated in FIG. 38 in the sixth embodiment, the sectional diagram of the imaging device that formation of the principal parts has been completed.

FIG. 40 is a sectional diagram illustrating one example of one process of a manufacturing method for an imaging device according to a seventh embodiment.

FIG. 41 is a sectional diagram illustrating one example of one process to be performed after the process illustrated in FIG. 40 in the seventh embodiment.

FIG. 42 is a sectional diagram illustrating one example of one process to be performed after the process illustrated in FIG. 41 in the seventh embodiment.

FIG. 43 is a sectional diagram illustrating one example of one process to be performed after the process illustrated in FIG. 42 in the seventh embodiment, the sectional diagram of the imaging device that formation of the principal parts has been completed.

### DETAILED DESCRIPTION

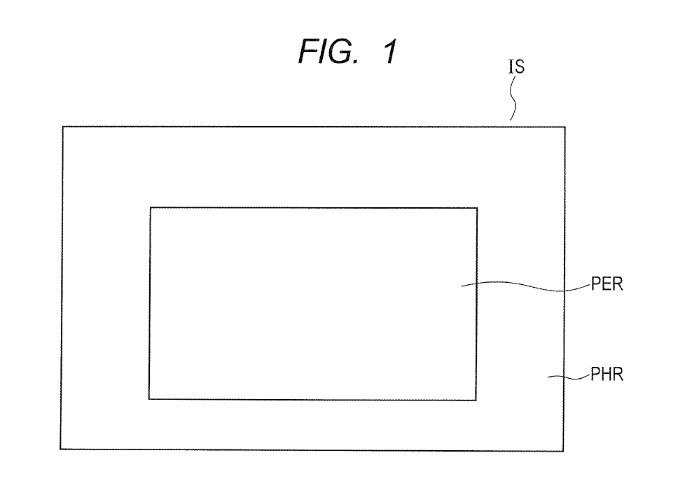

First, one example of a planar structure of an imaging device according to each embodiment will be described. As illustrated in FIG. 1, in an imaging device IS, a peripheral circuit region PHR is arranged so as to surround a pixel region PER that receives light. A photodiode that photo-electrically converts the received light is formed in the pixel region PER. Further, a pixel transistor (a pixel element) such as an amplification transistor and so forth configured to output electrons generated in the photodiode as an analog signal is formed. A peripheral circuit element that performs correction such as removal of noises from the output analog signal and so forth, converts the analog signal so corrected into a digital signal and outputs the digital signal is formed in the peripheral circuit region PHR. In the following, in each of the embodiments, examples of structures of the pixel region PER and the peripheral circuit region PHR will be specifically described.

### First Embodiment

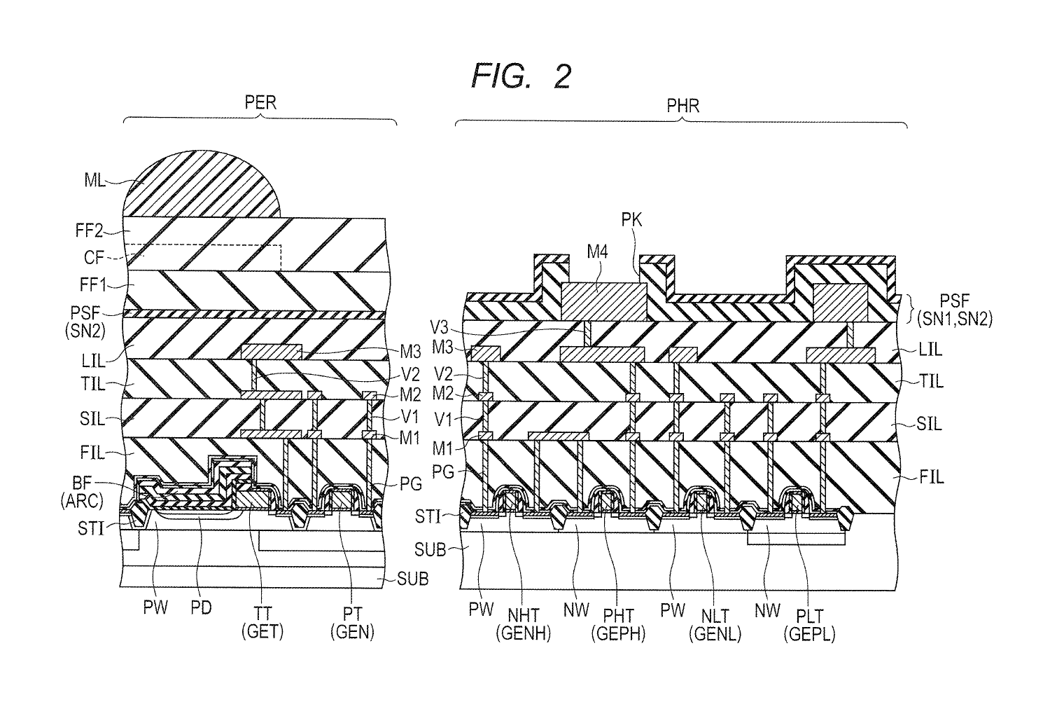

An imaging device according to a first embodiment will be described. As illustrated in FIG. 2, the pixel region PER and the peripheral circuit region PHR are defined by separation insulation films STI on a semiconductor substrate SUB. A P-type well PW is formed in the pixel region PER. A transfer transistor TT that includes a photodiode PD, a gate electrode GET and so forth, and a pixel transistor PT that includes a gate electrode GEN and so forth are formed over the P-type well PW. A protection film BF that includes an anti-reflection film ARC and so forth is formed so as to cover the photodiode PD.

A plurality of the P-type wells PW and a plurality of N-type wells NW are formed in the peripheral circuit region PHR. An NMOS transistor NHT that includes a gate electrode GENH and so forth is formed over one P-type well PW. An NMOS transistor NLT that includes a gate electrode GENL and so forth is formed over another P-type well PW. In addition, a PMOS transistor PHT that includes a gate electrode GEPH and so forth is formed over one N-type well NW. A PMOS transistor PLT that includes agate electrode GEPL and so forth is formed over another N-type well NW.

The NMOS transistor NHT and the PMOS transistor PHT each is a field effect transistor that drives with a high voltage of, for example, about 3.3 V. On the other hand, the NMOS transistor NLT and the PMOS transistor PLT each is a field effect transistor that drives with a low voltage of, for example, about 1.5 V.

A first interlayer insulation film FIL is formed so as to cover the photodiode PD, the transfer transistor TT, the pixel transistor PT, the NMOS transistor NHT, the PMOS transistor PHT, the NMOS transistor NLT, the PMOS transistor PLT and so forth.

A plurality of first wiring layers M1 are formed over a surface of the first interlayer insulation film FIL. The first wiring layer MI concerned and the predetermined pixel transistor PT and so forth are electrically coupled together via a plug PG in the pixel region PER. The first wiring layer M1 concerned and one predetermined peripheral transistor such as the NMOS transistor NHT and so forth are electrically coupled together via the plug PG in the peripheral circuit region PHR.

A second interlayer insulation film SIL is formed so as to cover the plurality of first wiring layers M1. A plurality of second wiring layers M2 are formed over a surface of the second interlayer insulation film SIL. The second wiring layer M2 concerned and one predetermined wiring layer M1 are electrically coupled together via a via-hole V1 in the pixel region PER. The second wiring layer M2 concerned and one predetermined first wiring layer M1 are electrically coupled together via the via hole V1 in the peripheral circuit region PHR.

A third interlayer insulation film TIL is formed so as to cover the plurality of second wiring layers M2. A plurality of third wiring layers M3 are formed over a surface of the third interlayer insulation film TIL. The third wiring layer M3 concerned and one predetermined second wiring layer M2 are electrically coupled together via a via hole V2 in the pixel region PER. The third wiring layer M3 concerned and one predetermined second wiring layer M2 are electrically coupled together via the via hole V2 in the peripheral circuit region PHR.

A fourth interlayer insulation film LIL is formed so as to cover the plurality of third wiring layers M3. In the imaging device according to the first embodiment, the fourth interlayer insulation film LIL serves as an interlayer insulation film that is situated on the uppermost layer. Fourth wiring layers M4 that include pads are further formed over a surface of the fourth interlayer insulation film LIL in the peripheral circuit region PHR. On the other hand, any wiring layer corresponding to the fourth wiring layer M4 is not formed in the pixel region PER.

A passivation film PSF (an interposition film) is formed in contact with the fourth interlayer insulation film LIL in the pixel region PER and is formed so as to cover the fourth wiring layers M4 in contact with the fourth interlayer insulation film LIL in the peripheral circuit region PHR. The passivation film PSF is interposed between a later described color filter CF and the fourth interlayer insulation film LIL. Pad openings PK through which the fourth wiring layers M4 that serve as pads are respectively exposed are formed in the passivation film PSF in the peripheral circuit region PHR.

In the imaging device according to the first embodiment, a film thickness of the passivation film PSF that is situated in the peripheral circuit region PHR is thicker than a film thickness of the passivation film PSF that is situated in the pixel region PER. Here, the passivation film PSF that is situated in the peripheral circuit region PHR is configured by two silicon nitride films, that is, a silicon nitride film SN1 and a silicon nitride film SN2. The passivation film PSF that is situated in the pixel region PER is configured by one silicon nitride film, that is, the silicon nitride film SN2.

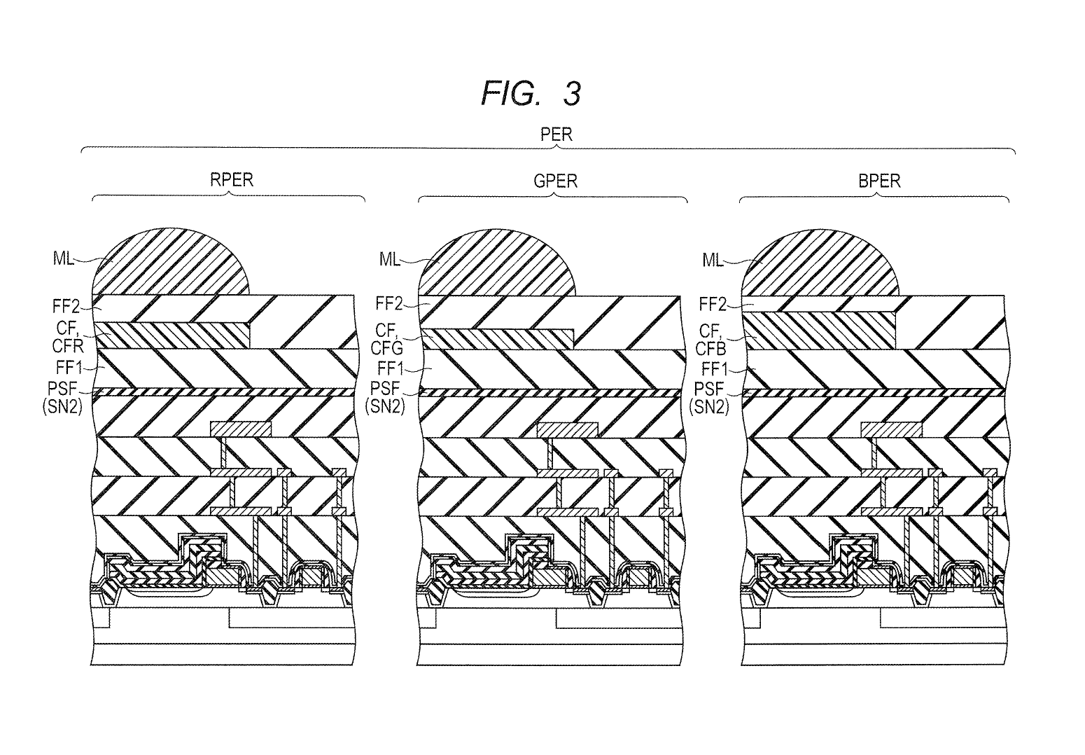

A flattening film FF1 is formed in contact with the passivation film PSF in the pixel region PER. The color filter CF is formed in contact with the flattening film FF1. A thickness of the color filter CF is different depending on each pixel region of a red pixel region, a green pixel region and a blue pixel region. As illustrated in FIG. 3, the thickness of a color filter CFG that is formed in a green pixel region GPER is the thinnest, and the thickness of a color filter CFB that is formed in a blue pixel region BPER is the thickest. A color filter CFR that is formed in a red pixel region RPER has a thickness between those of the color filter CFG and the color filter CFB.

A flattening film FF2 that covers the color filters CFR, CFG and CFB that are different from one another in thickness so as to flatten the color filters CFR, CFG and CFB is further formed in the pixel region PER. A microlens ML is arranged over a surface of the flattening film FF2. Principal parts of the imaging device are configured as described above.

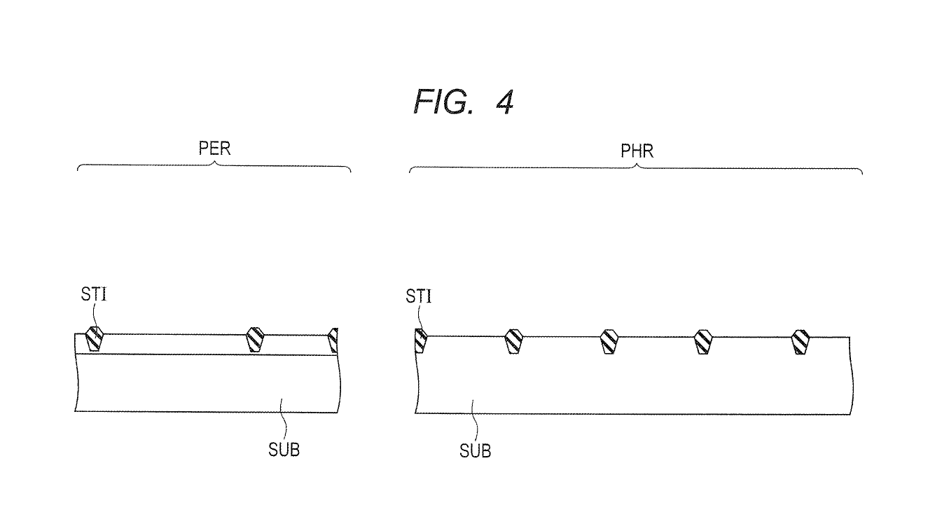

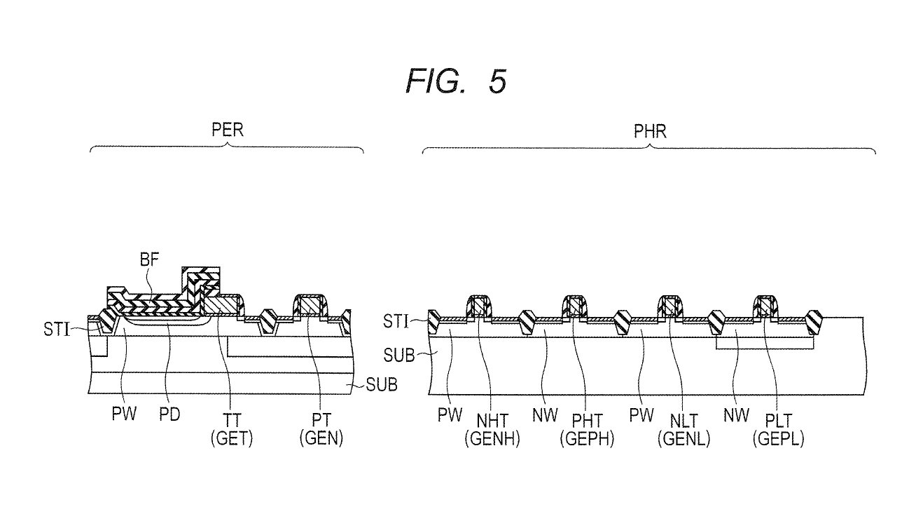

Then, one example of a manufacturing method for the above-mentioned imaging device will be described. As illustrated in FIG. 4, the separation insulation films STI are formed on the semiconductor substrate SUB by, for example, a trench separation method. Then, as illustrated in FIG. 5, the P-type wells PW are formed by implanting P-type impurities into the semiconductor substrate SUB. In addition, the N-type wells NW are formed by implanting N-type impurities into the semiconductor substrate SUB.

Thereafter, the transfer transistor TT that includes the photodiode PD, the protection film BF, the gate electrode GET and so forth and the pixel transistor PT that includes the gate electrode GEN and so forth are formed in the pixel region PER by performing implantation of the N-type impurities, implantation of the P-type impurities, patterning of a conductive film and so forth. The NMOS transistor NHT, the PMOS transistor PHT, the NMOS transistor NLT, the PMOS transistor PLT and so forth are formed in the peripheral circuit region PHR similarly.

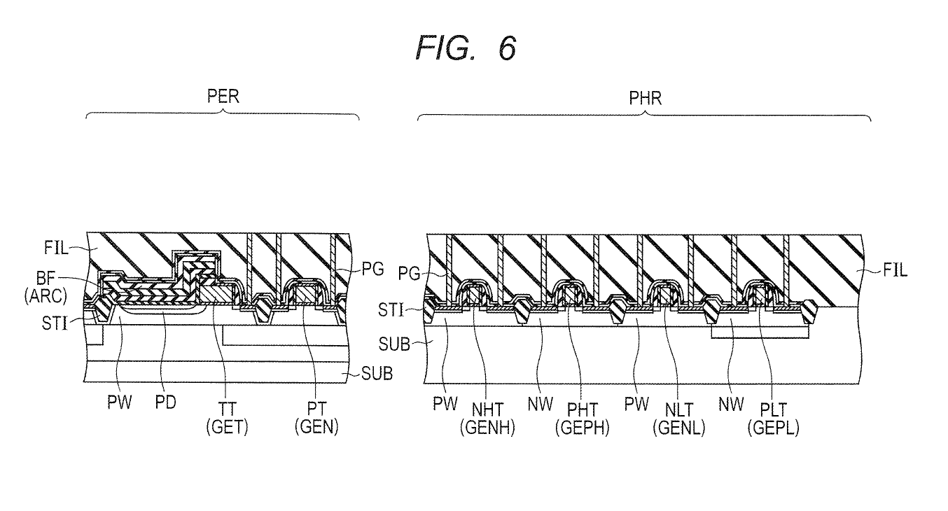

Then, the first interlayer insulation film FIL (see FIG. 6) that is configured by, for example, a TEOS (Tetra Ethyl Ortho Silicate) oxide film and so forth is formed so as to cover the photodiode PD, the NMOS transistor NHT and so forth. Then, a contact hole that runs through the first interlayer insulation film FIL is formed and a conductive film that includes a barrier film is formed in the contact hole. Thereafter, the plugs PG that run through the first interlayer insulation film FIL are formed by performing, for example, chemical mechanical polishing treatment on the first interlayer insulation film FIL as illustrated in FIG. 6.

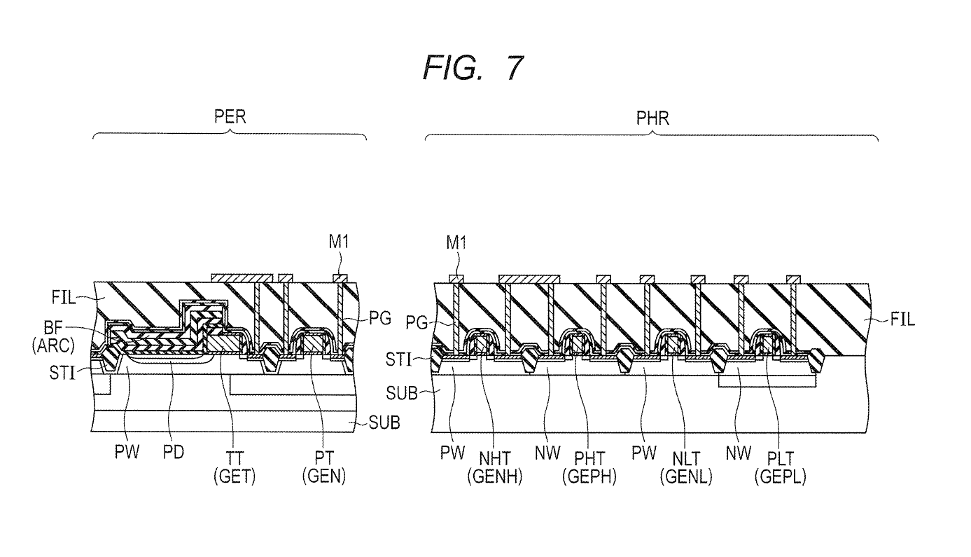

Then, a conductive film (not illustrated) such as, for example, an aluminum film and so forth is formed so as to cover the first interlayer insulation film FIL. Then, the first wiring layers M1 are formed as illustrated in FIG. 7 by performing predetermined photoengraving process and etching process on the conductive film.

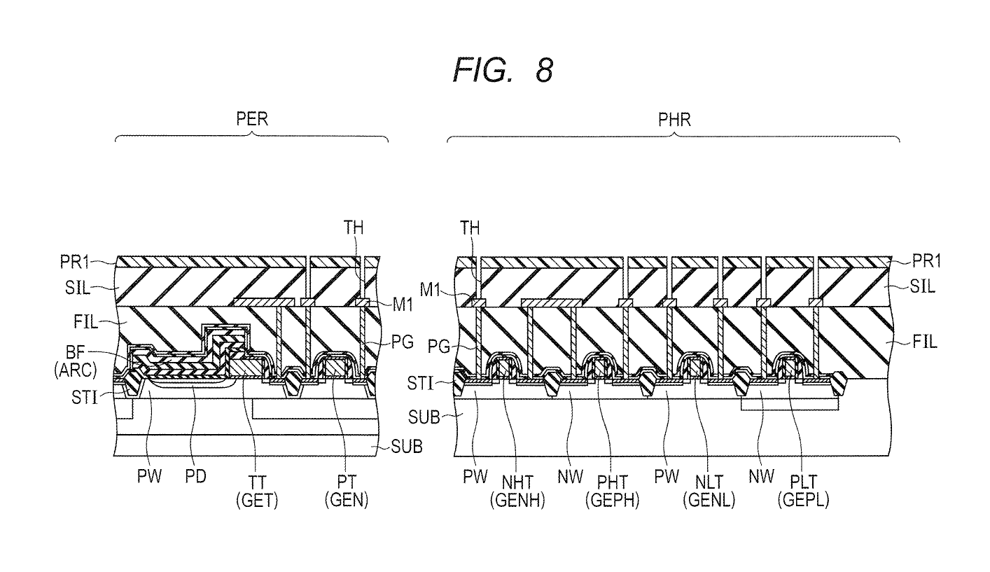

Then, as illustrated in FIG. 8, the second interlayer insulation film SIL is formed so as to cover the first wiring layers M1. Then, a photoresist pattern PR1 is formed by performing the predetermined photoengraving process. Then, through-holes TH through which the first wiring layers M1 are exposed to the outside are formed by performing the etching process on the second interlayer insulation film SIL by using the photoresist pattern PR1 as an etching mask. Thereafter, the photoresist pattern PR1 is removed.

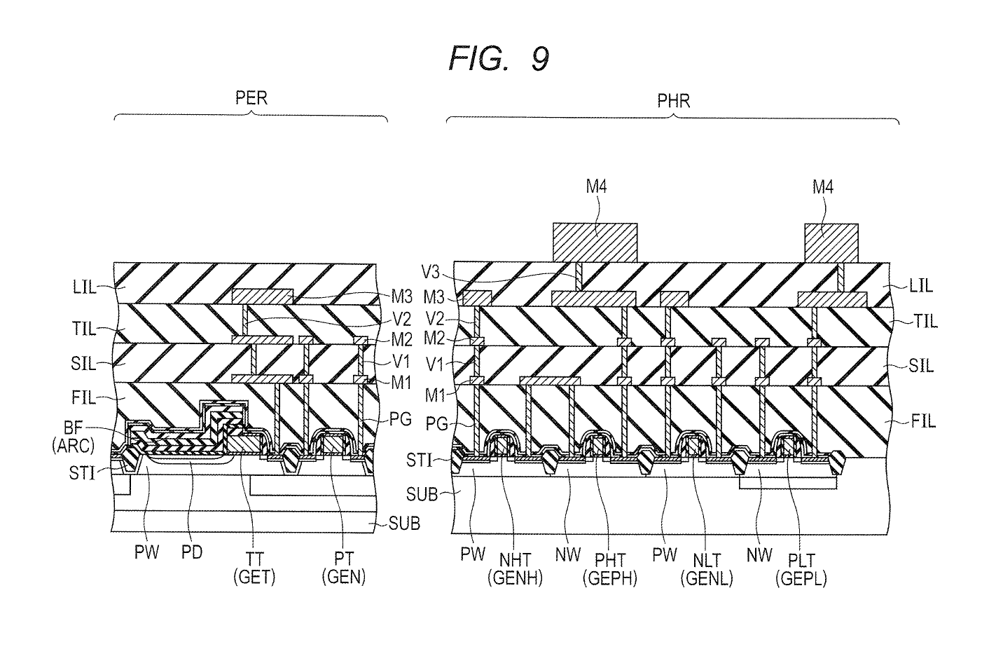

Then, as illustrated in FIG. 9, the via holes V1 are formed by forming conductive films that includes barrier films in the through-holes TH. Then, a conductive film (not illustrated) is formed so as to cover the second interlayer insulation film SIL and the second wiring layers M2 are formed by performing the predetermined photoengraving process and etching process on the conductive film. Then, the third interlayer insulation film TIL is formed so as to cover the second wiring layers M2. Then, the via holes V2 are formed so as to run through the third interlayer insulation film TIL by the same process as the process of forming the via holes V1.

Then, a conductive film (not illustrated) is formed so as to cover the second interlayer insulation film SIL, and the third wiring layers M3 are formed by performing the predetermined photoengraving process and etching process on the conductive film. Then, the fourth interlayer insulation film LIL is formed so as to cover the third wiring layers M3. The fourth interlayer insulation film LIL serves as the uppermost interlayer insulation film. Then, via holes V3 that run through the fourth interlayer insulation film LIL are formed in the fourth interlayer insulation film LIL that is situated in the peripheral circuit region PHR.

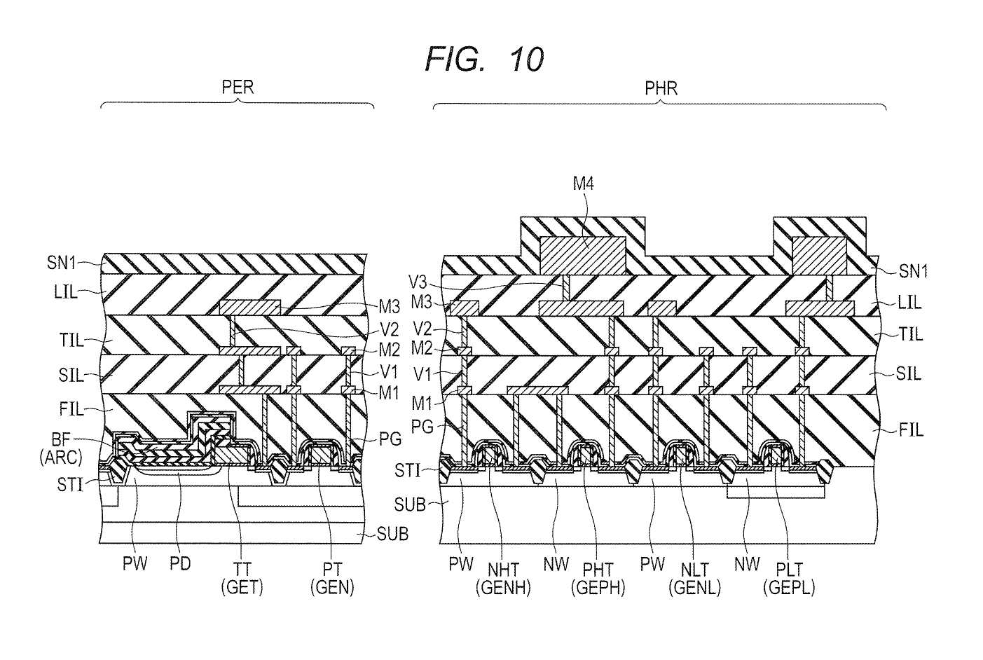

Then, a conductive film (not illustrated) is formed so as to cover the fourth interlayer insulation film LIL, and the fourth wiring layers M4 that include the pads are formed in the peripheral circuit region PHR by performing the predetermined photoengraving process and etching process on the conductive film. On the other hand, any new wiring layer is not formed in the pixel region PER. Then, as illustrated in FIG. 10, the silicon nitride film SN1 that is about 700 nm to about 800 nm in film thickness is formed so as to cover the fourth interlayer insulation film LIL by, for example, a plasma CVD (Chemical Vapor Deposition) method. The silicon nitride film SN1 configures a part of the passivation film in the peripheral circuit region PHR.

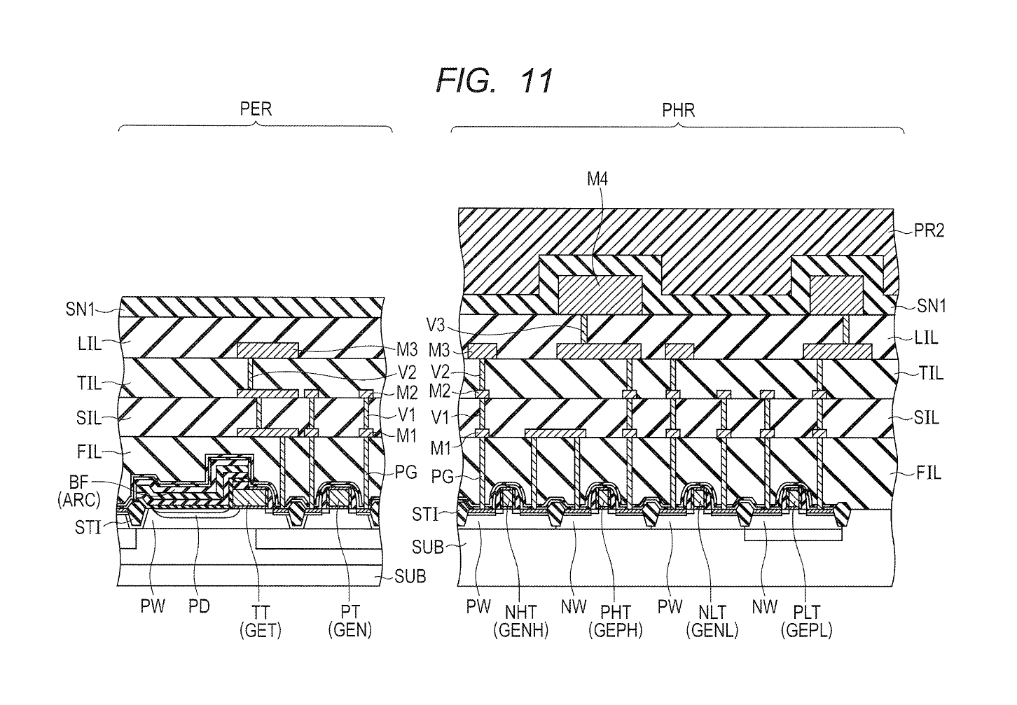

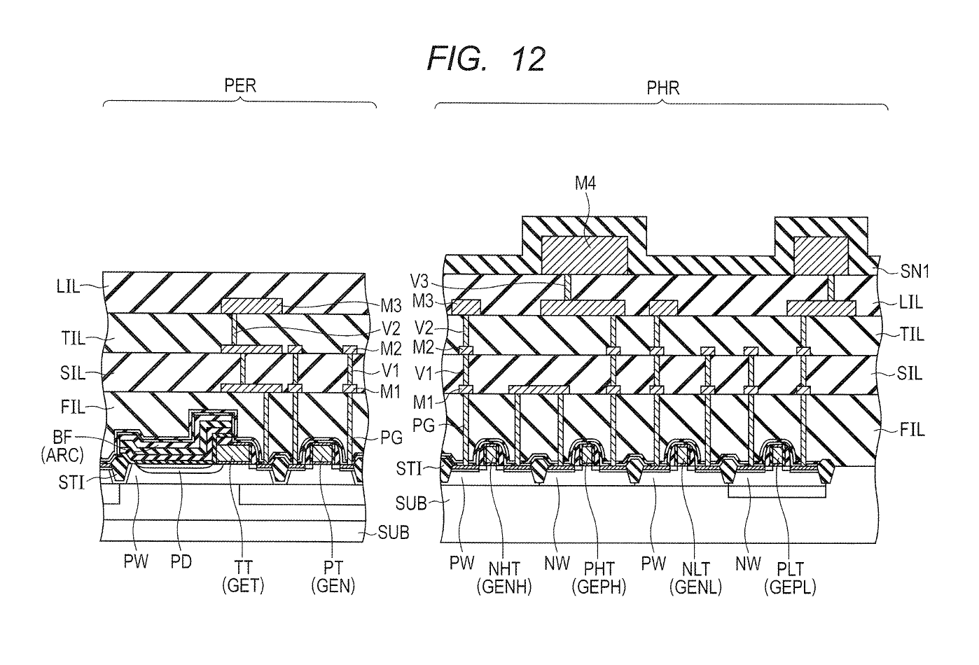

Then, as illustrated in FIG. 11, a photoresist pattern PR2 that exposes the pixel region PER and covers the peripheral circuit region PHR is formed by performing the predetermined photoengraving process. Then, as illustrated in FIG. 12, the silicon nitride film SN1 that is situated in the pixel region PER is removed and the fourth interlayer insulation film LIL is exposed to the outside by performing the etching process on the exposed silicon nitride film SN1 by using the photoresist pattern PR2 as an etching mask. Thereafter, the photoresist pattern PR2 is removed.

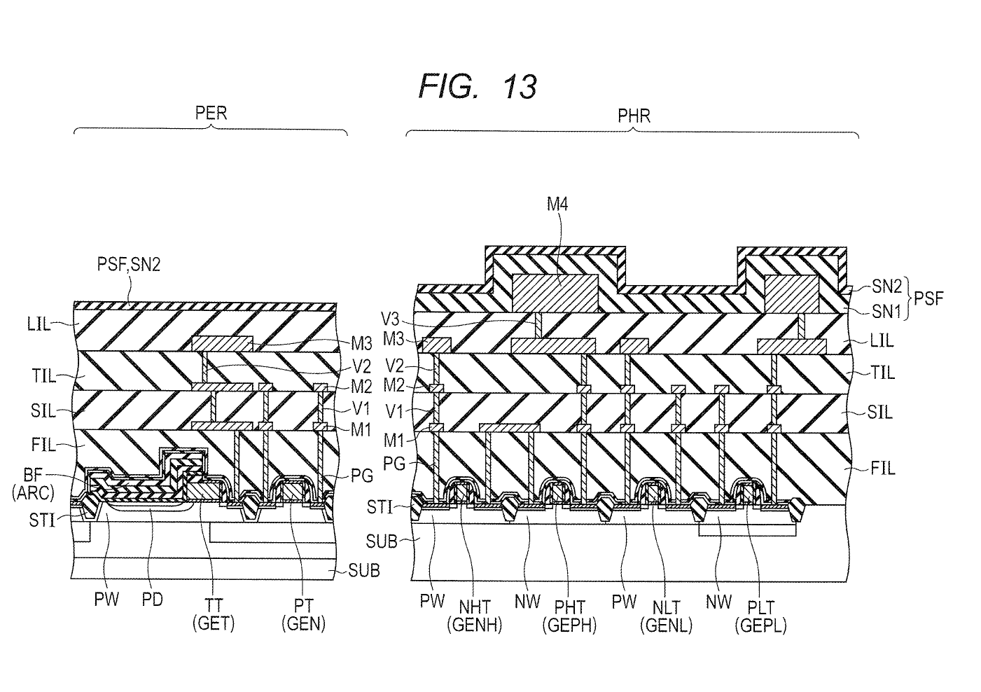

Then, as illustrated in FIG. 13, the silicon nitride film SN2 that is about 200 nm to about 300 nm in film thickness is formed by, for example, the plasma CVD method. The silicon nitride film SN2 is formed so as to cover the fourth interlayer insulation film LIL in the pixel region PER. The silicon nitride film SN2 is formed so as to cover the silicon nitride film SN1 in the peripheral circuit region PHR. The passivation film PSF that includes the silicon nitride film SN2 and so forth is formed in the pixel region PER in this way. The passivation film PSF that includes the silicon nitride film SN1, the silicon nitride film SN2 and so forth is formed in the peripheral circuit region PHR.

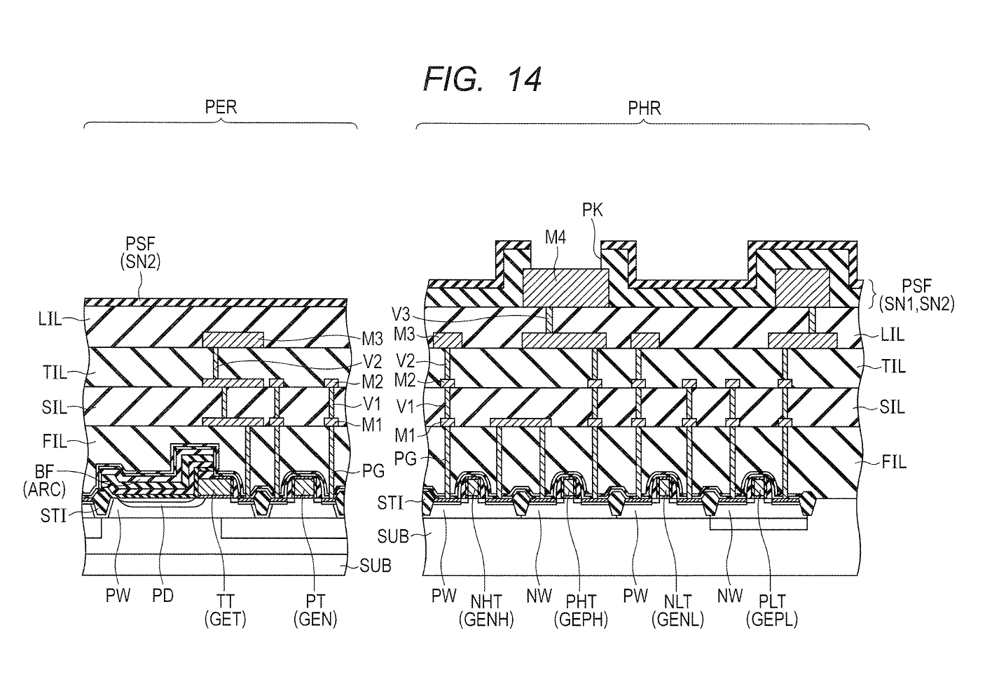

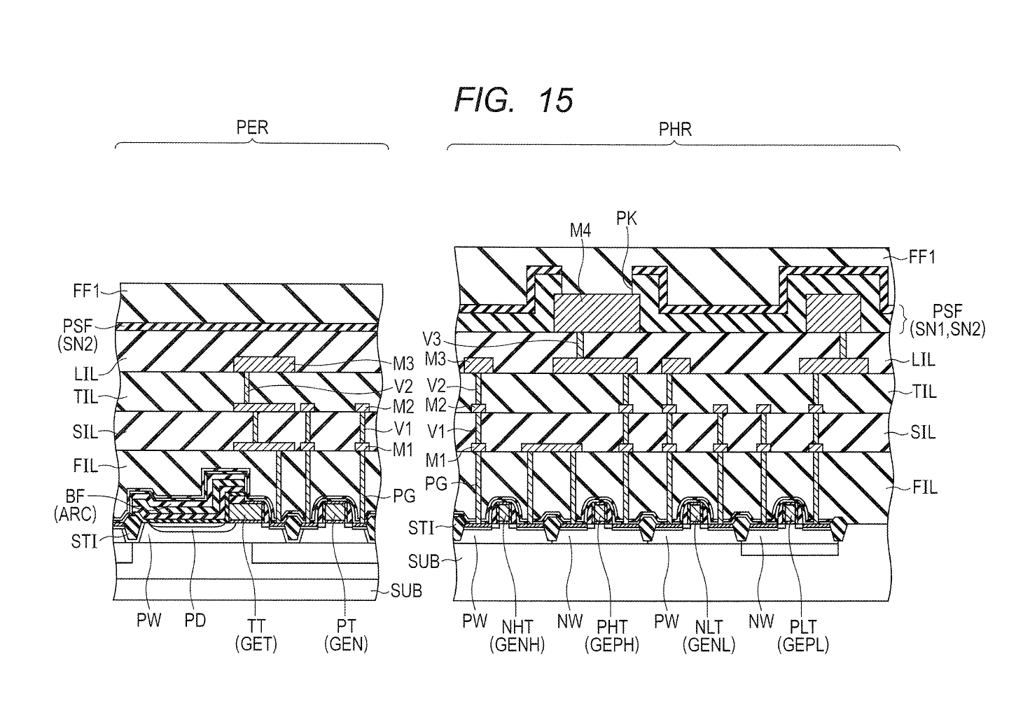

Then, the pad openings PK through which the fourth wiring layers M4 that serves as the pads are exposed to the outside are formed in parts of the passivation film PSF that is situated in the peripheral circuit region PHR by performing the predetermined photoengraving process and etching process as illustrated in FIG. 14. Then, as illustrated in FIG. 15, the flattening film FFq1 is formed so as to cover a level difference generated due to formation of the pad openings PK and so forth in the peripheral circuit region PHR. An organic material is used as the material of the flattening film FF1 and the flattening film FF1 is formed by applying the organic material to the passivation film PSF.

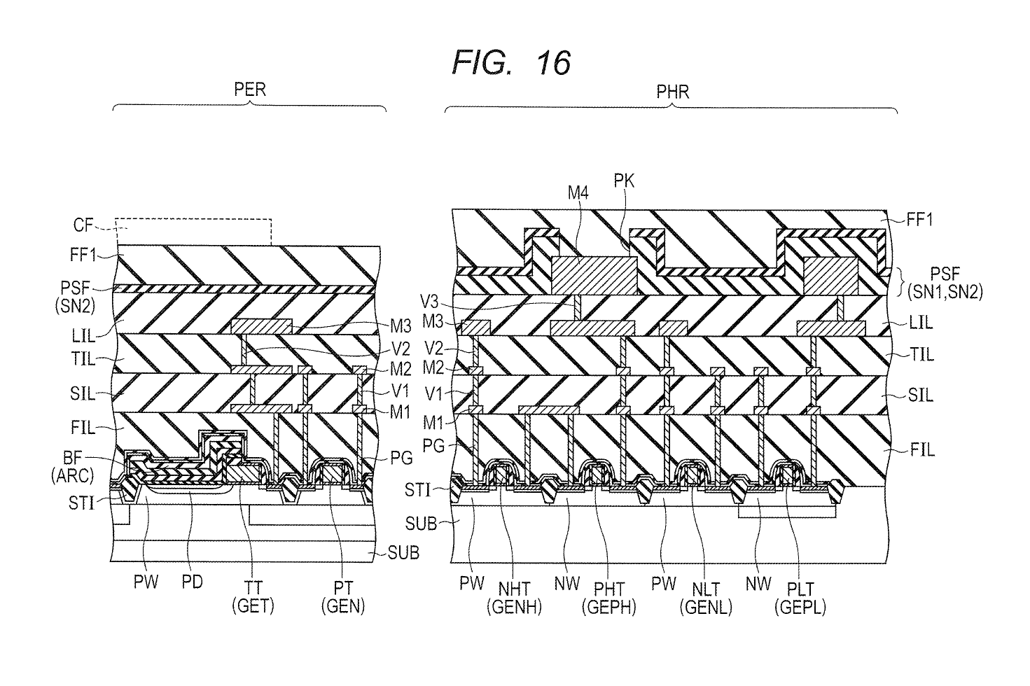

Then, as illustrated in FIG. 16, the color filter CF is formed. A photoresist that contains a pigment is used as the material of the color filter CF. The color filter CF is formed by applying the photoresist to the flattening film FF1 and performing the predetermined photoengraving process on the photoresist. On this occasion, the color filters CFR, CFG and CFB that respectively correspond to the red pixel region RPER, the green pixel region GPER and the blue pixel region BPER and are mutually different in thickness are respectively formed (see FIG. 3).

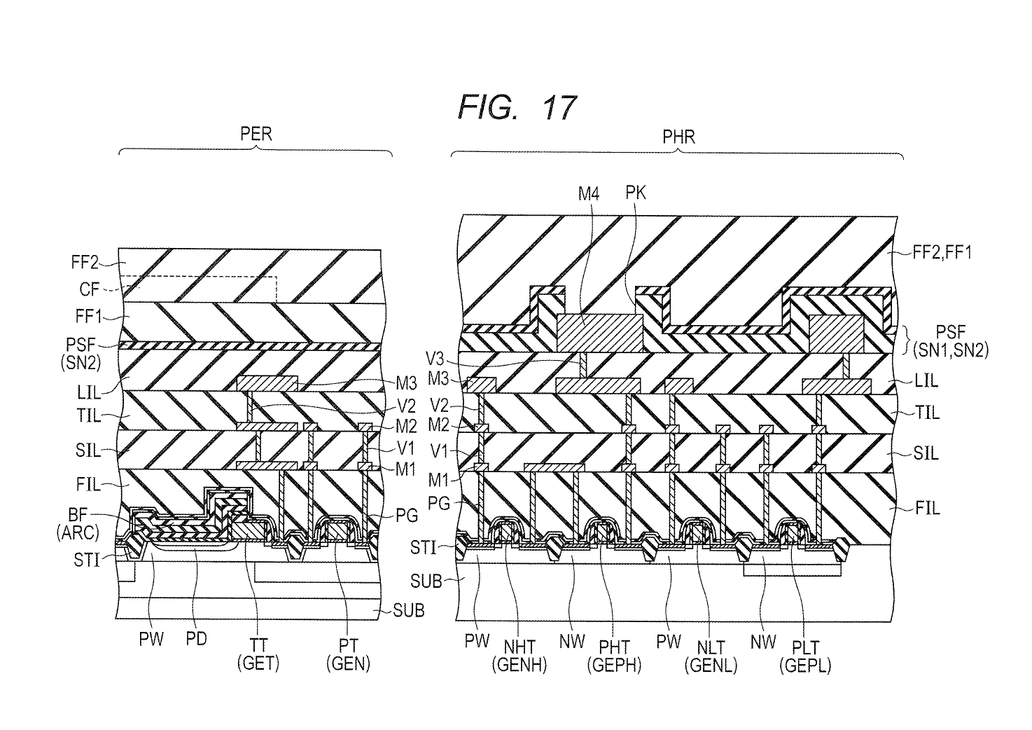

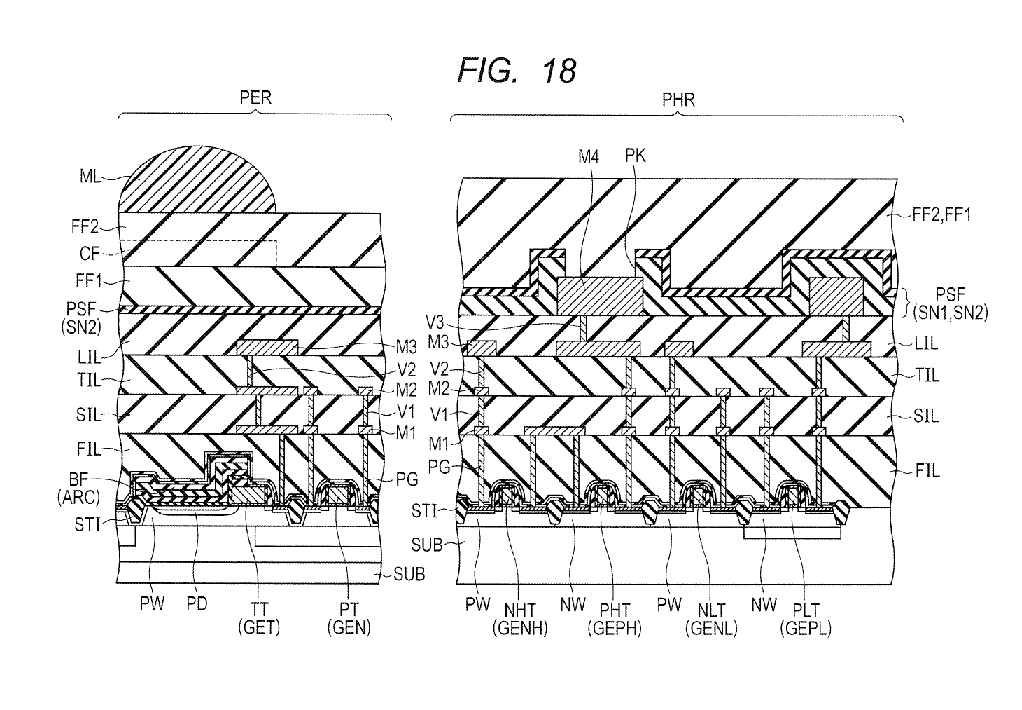

Then, as illustrated in FIG. 17, the flattening film FF2 is formed so as to cover the level difference among the color filters CF (CFR, CFG and CFB) that are mutually different in thickness. The same organic material as that of the flattening film FF1 is used as the material of the flattening film FF2. The flattening film FF2 is formed by applying the organic material onto the color filters. Then, as illustrated in FIG. 18, the microlens ML is formed in the pixel region PER. An organic material is used as the material of the microlens ML. The microlens ML is formed by applying the organic material onto the flattening film FF2 and performing the predetermined photoengraving process and a predetermined reflow process.

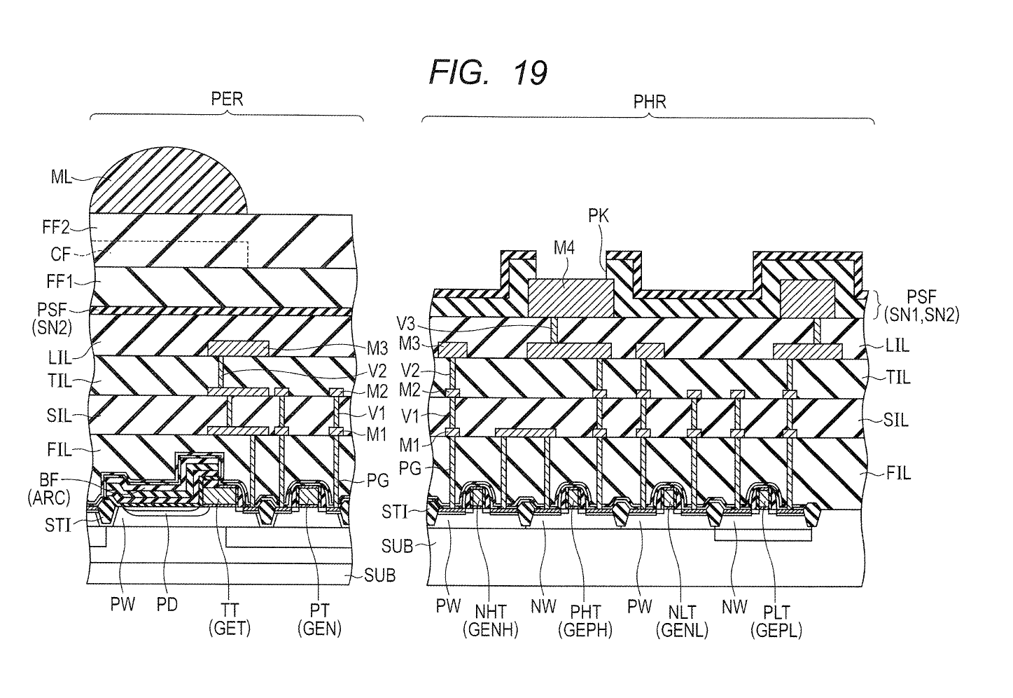

Then, a photoresist pattern (not illustrated) that covers the pixel region PER and exposes the peripheral circuit region PHR is formed by performing the predetermined photoengraving process. Then, the flattening films FF2 and FF1 that are situated in the peripheral circuit region PHR are removed by performing the etching process on the exposed flattening films FF2 and FF1 by using the photoresist pattern as the etching mask as illustrated in FIG. 19. Thereafter, the photoresist pattern is removed. The principal parts of the imaging device are formed in this way.

In the above-mentioned imaging device, the film thickness of the passivation film PSF that is situated in the peripheral circuit region PHR is made thicker than the film thickness of the passivation film PSF that is situated in the pixel region PER. Thereby, it is possible to sufficiently ensure the humidity resistance in the peripheral circuit region. The imaging device according to the first embodiment will be described in comparison with an imaging device according to a comparative example with respect to this point.

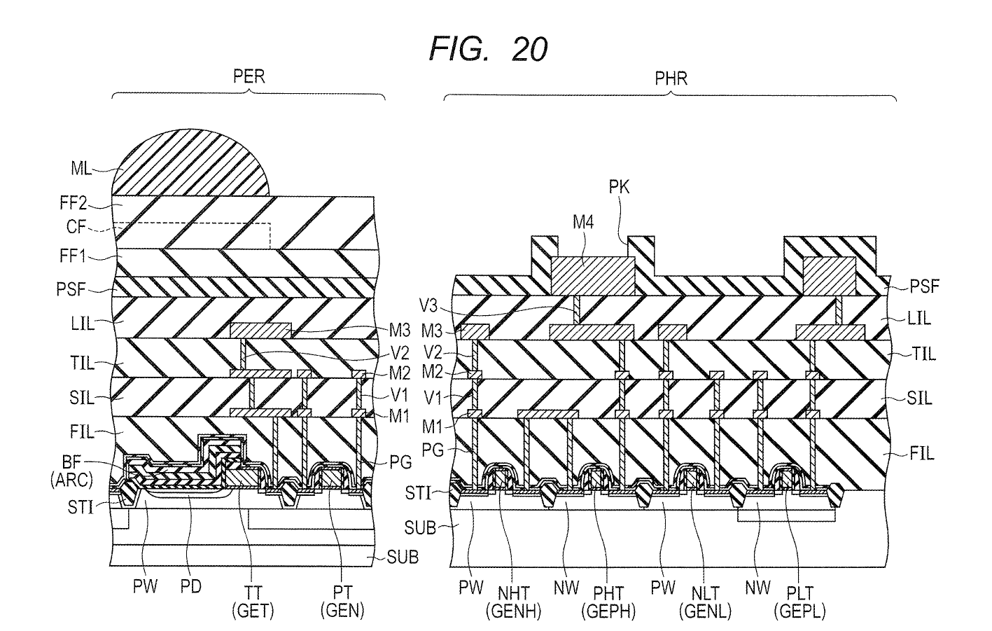

As illustrated in FIG. 20, in the imaging device according to the comparative example, the passivation film PSF that is situated in the peripheral circuit region PHR is formed so as to have the same film thickness as the passivation film PSF that is situated in the pixel region PER. Incidentally, since other configurations are the same as those of the imaging device illustrated in FIG. 2, the same numerals are assigned to the same members and the description thereon is not repeated unless otherwise requested.

As already described, a passivation film that is comparatively thin in film thickness is formed as the passivation film PSF in order to suppress the attenuation of the incident light in the pixel region PER. Therefore, when the passivation film PSF to be formed in the peripheral circuit region PHR is formed having the film thickness that is the same as the comparatively thin film thickness as described above, it is anticipated that it will become difficult to sufficiently ensure the humidity resistance of the imaging device.

In contrast to the imaging device according to the comparative example, in the imaging device according to the first embodiment, the passivation film PSF that is situated in the pixel region PER is configured by a single silicon nitride film, that is, the silicon nitride film SN2. On the other hand, the passivation film PSF that is situated in the peripheral circuit region PHR is configured by two silicon nitride films, that is, the silicon nitride film SN1 and the silicon nitride film SN2.

Thereby, the passivation film PSF that is situated in the peripheral circuit region PHR is formed with the film thickness that is thicker than the film thickness of the passivation film PSF that is situated in the pixel region PER. Consequently, it is possible to sufficiently ensure the humidity resistance of the imaging device and it is possible to improve reliability of the imaging device.

In addition, in the pixel region PER, it is possible to suppress the attenuation of the incident light and it is possible to suppress a reduction in sensitivity of the imaging device owing to formation of the passivation film that is comparatively thin in film thickness. In the imaging device according to the first embodiment, it is possible to promote improvement of the humidity resistance and improvement of the sensitivity in this way.

### Second Embodiment

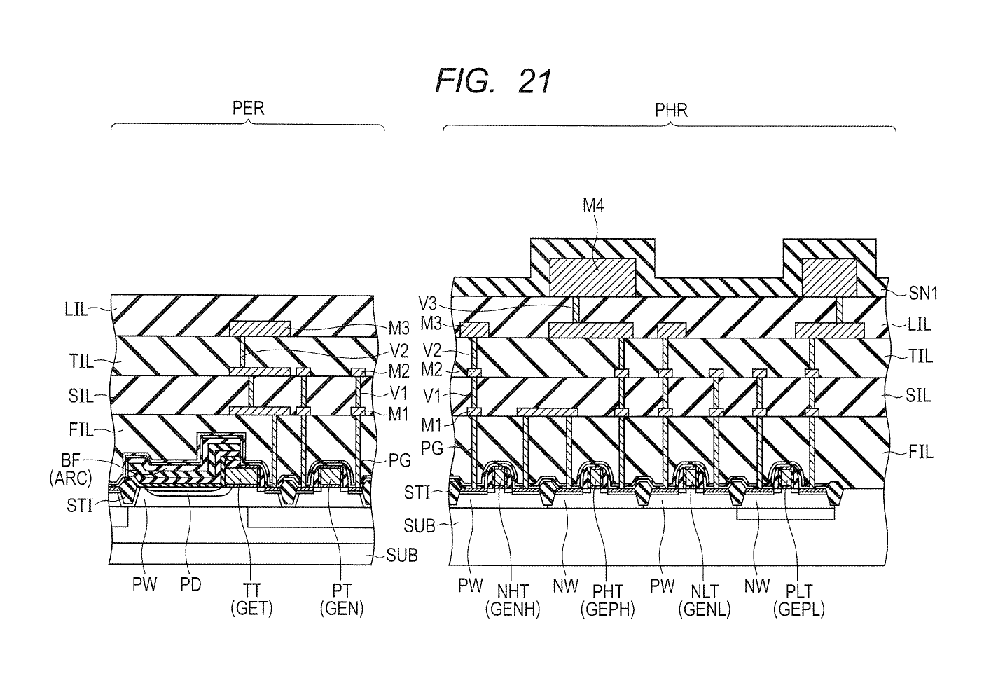

An imaging device according to the second embodiment will be described. First, one example of a manufacturing method for the imaging device will be described. Incidentally, in the second and successive embodiments, the same numerals are assigned to the same members as those in the first embodiment and description thereon will be made as requested. First, as illustrated in FIG. 21, the silicon nitride film SN1 that covers the fourth interlayer insulation film LIL is left as it is in the peripheral circuit region PHR and the silicon nitride film SN1 is removed and the fourth interlayer insulation film LIL is exposed to the outside in the pixel region PER through the same processes as those illustrated in FIG. 4 to FIG. 12.

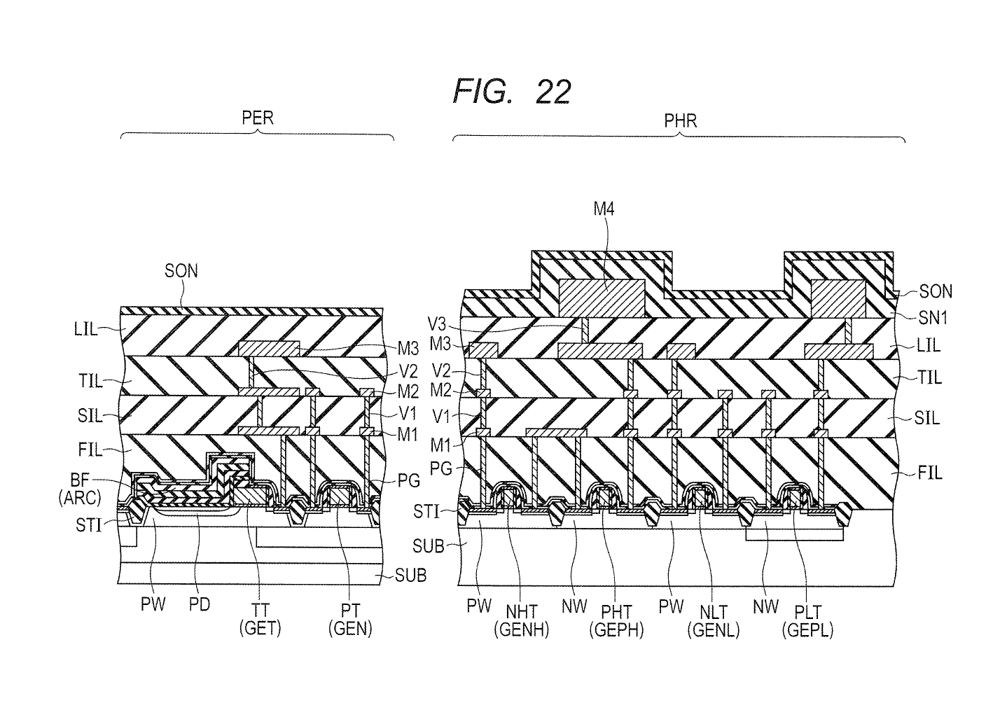

Then, as illustrated in FIG. 22, a silicon oxynitride film SON that is about 50 nm to about 80 nm in film thickness is formed by, for example, the plasma CVD method. The silicon oxynitride film SON is formed so as to cover the fourth interlayer insulation film LIL in the pixel region PER. The silicon oxynitride film SON is formed so as to cover the silicon nitride film SN1 in the peripheral circuit region PHR.

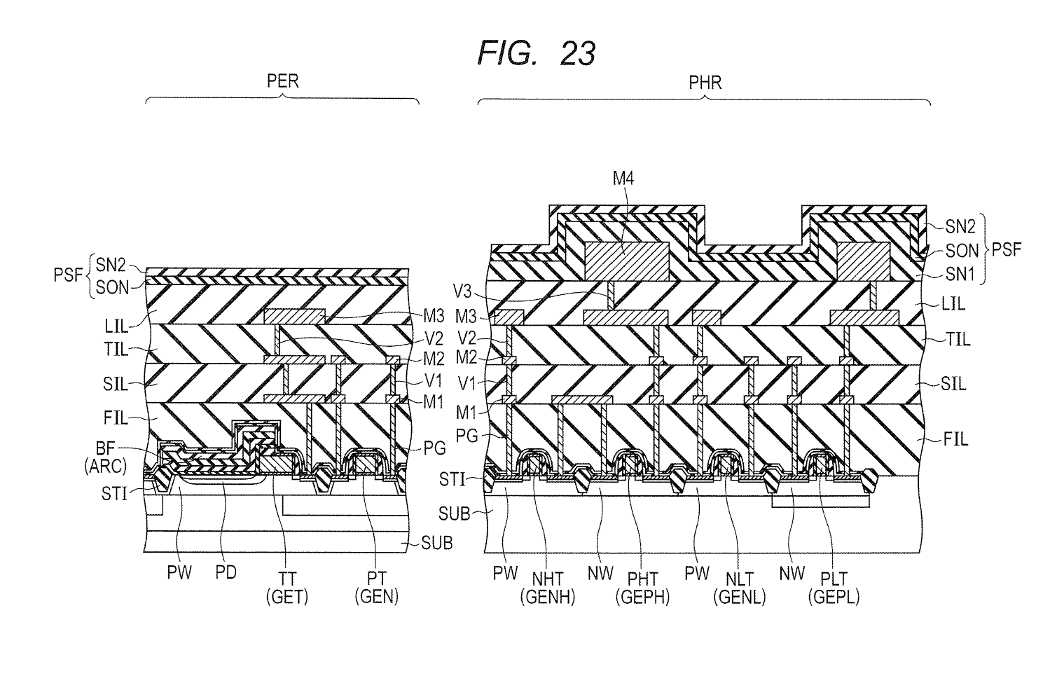

Then, as illustrated in FIG. 23, the silicon nitride film SN2 that is about 200 nm to about 300 nm in film thickness is formed by, for example, the plasma CVD method. The silicon nitride film SN2 is formed so as to cover the silicon oxynitride film SON in the pixel region PER. The silicon nitride film SN2 is formed so as to cover the silicon oxynitride film SON in the peripheral circuit region PHR.

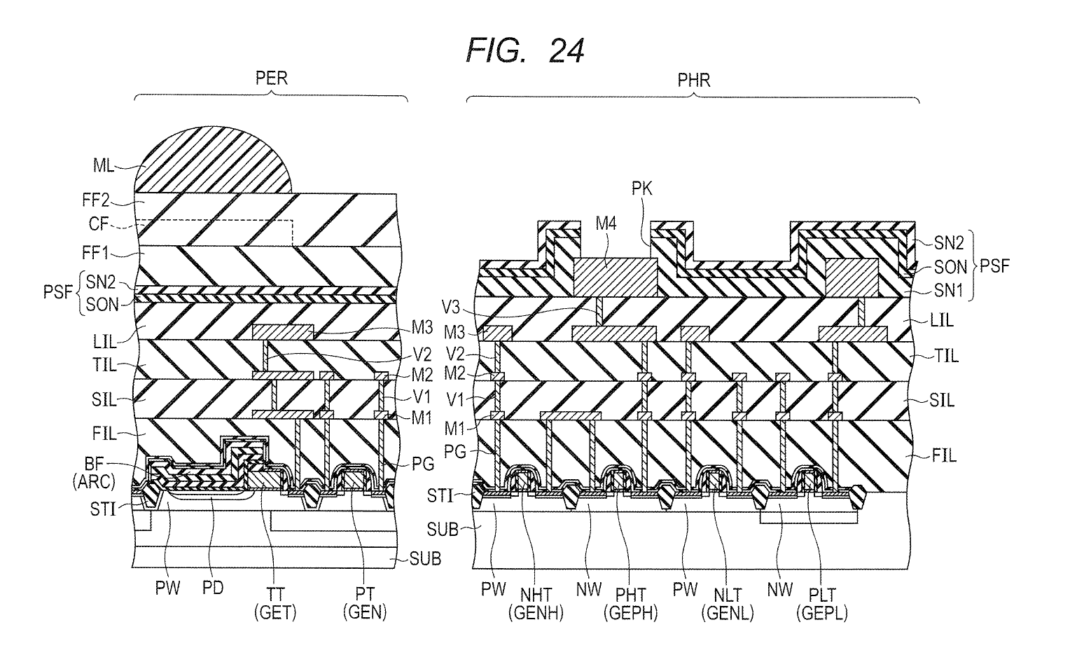

The passivation film PSF that the silicon nitride film SN2 is laminated over the silicon oxynitride film SON is formed in the pixel region PER in this way. The passivation film PSF that the silicon nitride film SN1, the silicon oxynitride film SON and the silicon nitride film SN2 are laminated is formed in the peripheral circuit region PHR. Thereafter, formation of the principal parts of the imaging device is completed through the same processes as the processes illustrated in FIG. 14 to FIG. 19 as illustrated in FIG. 24.

In the above-mentioned imaging device, the passivation film PSF that is situated in the pixel region PER includes the silicon oxynitride film SON, the silicon nitride film SN2 nd so forth. On the other hand, the passivation film PSF that is situated in the peripheral circuit region PHR includes the silicon nitride film SN1, the silicon oxynitride film SON, the silicon nitride film SN2 and so forth.

Thereby, the passivation film PSF that is situated in the peripheral circuit region PHR is formed with the film thickness that is thicker than the film thickness of the passivation film PSF that is situated in the pixel region PER. Consequently, it is possible to sufficiently ensure the humidity resistance of the imaging device and it is possible to improve the reliability of the imaging device.

Further, in the pixel region PER of the above-mentioned imaging device, it is possible to suppress reflection of the incident light from an interface between the passivation film PSF and the fourth interlayer insulation film LIL. Description will be made with respect to this point.

A refractive index n of the silicon nitride film SN2 is about 1.9. The refractive index n of the fourth interlayer insulation film LIL that includes the silicon oxide film such as the TEOS oxide film and so forth is about 1.4 to about 1.5. The refractive index n of the silicon oxynitride film SON is about 1.5 to about 1.7. The silicon oxynitride film SON is interposed between the fourth interlayer insulation film LIL and the silicon nitride film SN2 in the pixel region PER.

Thereby, a difference between the refractive index of the silicon oxynitride film SON (the passivation film PSF) and the refractive index of the fourth interlayer insulation film LIL becomes smaller than a difference between the refractive index of the silicon nitride film SN2 and the refractive index of the fourth interlayer insulation film LIL. Consequently, it is possible to suppress the reflection of the incident light from the interface between the silicon oxynitride film SON (the passivation film PSF) and the fourth interlayer insulation film LIL and it is possible to further improve the sensitivity of the imaging device.

According to the evaluation made by the inventors and others, when the imaging device was irradiated with light of a fixed intensity and a signal (a voltage value) that is output was evaluated, it was confirmed that the voltage value is increased by several percent in comparison with an imaging device that the silicon oxynitride film SON is not formed in the pixel region PER.

### Third Embodiment

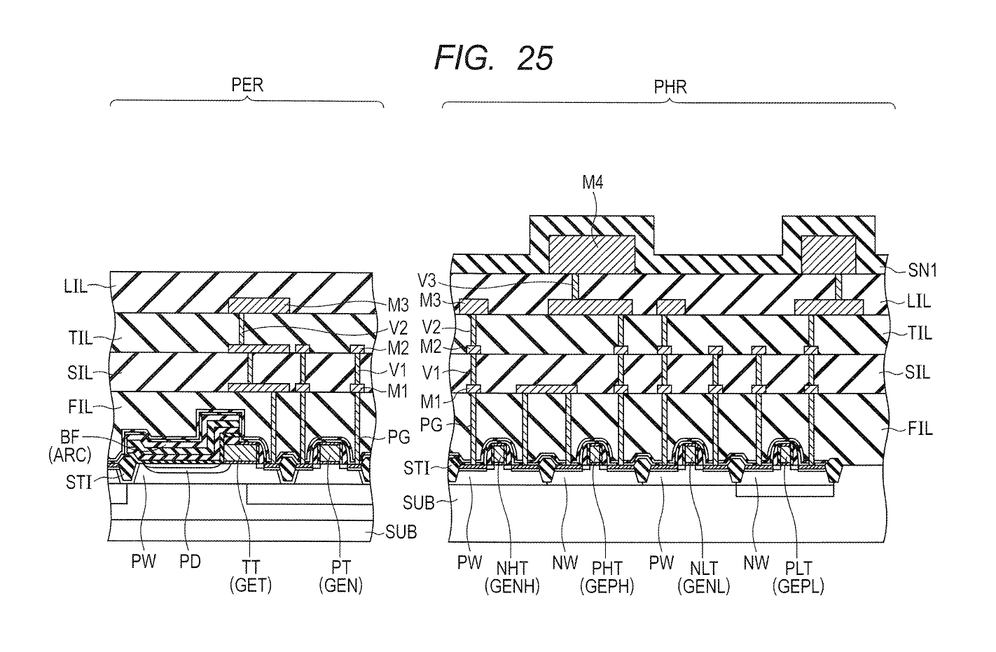

An imaging device according to the third embodiment will be described. First, one example of a manufacturing method for the imaging device will be described. First, as illustrated in FIG. 25, the silicon nitride film SN1 that covers the fourth interlayer insulation film LIL is left as it is in the peripheral circuit region PHR and the silicon nitride film is removed and the fourth interlayer insulation film LIL is exposed in the pixel region PER through the same processes as the processes illustrated in FIG. 4 to FIG. 12.

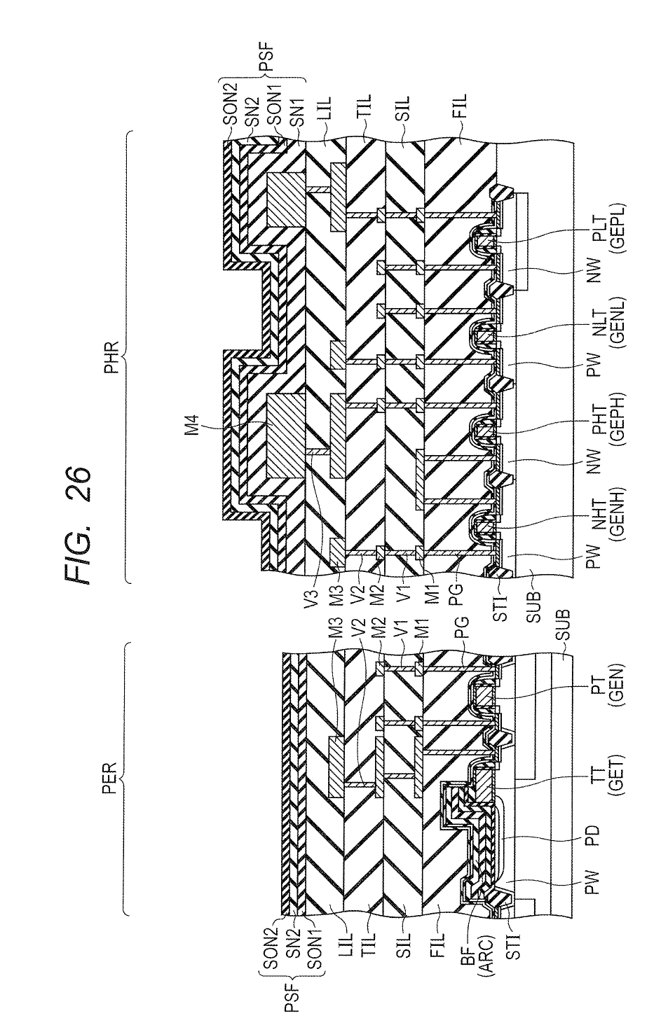

Then, as illustrated in FIG. 26, a silicon oxynitride film SON1 that is about 50 nm to about 80 nm in film thickness is formed by, for example, the plasma CVD method. The silicon oxynitride film SON1 is formed so as to cover the fourth interlayer insulation film in the pixel region PER. The silicon oxynitride film SON1 is formed so as to cover the silicon nitride film SN1 in the peripheral circuit region PHR.

Then, the silicon nitride film SN2 that is about 200 nm to about 300 nm in film thickness is formed by, for example, the plasma CVD method. The silicon nitride film SN2 is formed so as to cover the silicon oxynitride film SON1 in the pixel region PER. The silicon nitride film SN2 is formed so as to cover the silicon oxynitride film SON1 in the peripheral circuit region PHR.

Then, a silicon oxynitride film SON2 that is about 50 nm to about 80 nm in film thickness is further formed by, for example, the plasma CVD method. The silicon oxynitride film SON2 is formed so as to cover the silicon nitride film SN2 in the pixel region PER. The silicon oxynitride film SON2 is formed so as to cover the silicon nitride film SN2 in the peripheral circuit region PHR.

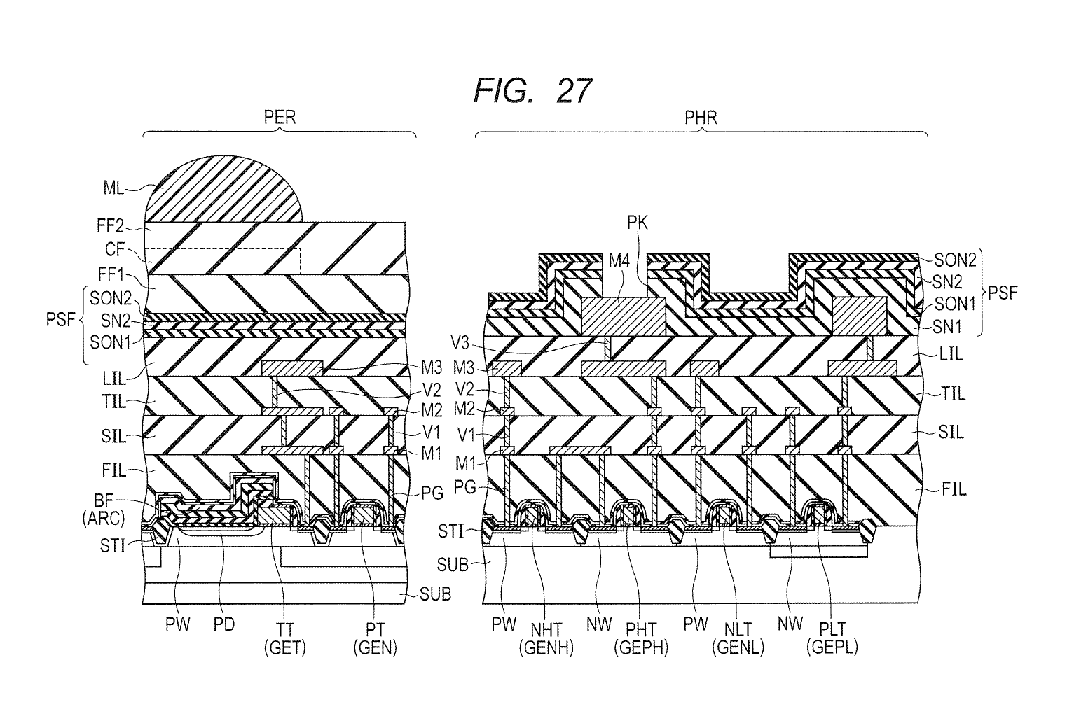

The passivation film PSF that the silicon oxynitride film SON1, the silicon nitride film SN2 and the silicon oxynitride film SON2 are laminated is formed in the pixel region PER in this way. The passivation film PSF that the silicon nitride film SN1, the silicon oxynitride film SON1, the silicon nitride film SN2 and the silicon oxynitride film SON2 are laminated is formed in the peripheral circuit region PHR. Thereafter, formation of the principal parts of the imaging device is completed through the same processes as the processes illustrated in FIG. 14 to FIG. 19 as illustrated in FIG. 27.

In the above-mentioned imaging device, the passivation layer PSF that is situated in the pixel region PER includes the silicon oxynitride film SON1, the silicon nitride film SN2, the silicon oxynitride film SON2 and so forth. On the other hand, the passivation film PSF that is situated in the peripheral circuit region PHR includes the silicon nitride film SN1, the silicon oxynitride film SON1, the silicon nitride film SN2, the silicon oxynitride film SON2 and so forth.

Thereby, the passivation film PSF that is situated in the peripheral circuit region PHR is formed with the film thickness that is thicker than the film thickness of the passivation film PSF that is situated in the pixel region PER. Consequently, it is possible to sufficiently ensure the humidity resistance of the imaging device and it is possible to improve the reliability of the imaging device.

In addition, in the pixel region PER of the above-mentioned imaging device, the silicon oxynitride film SON1 is interposed between the fourth interlayer insulation film LIL and the silicon nitride film SN2 similarly to the configuration described in the second embodiment. Thereby, the difference between the refractive index of the silicon oxynitride film SON1 and the refractive index of the fourth interlayer insulation film LIL becomes smaller than the difference between the refractive index of the silicon nitride film SN2 and the refractive index of the fourth interlayer insulation film LIL and thereby it is possible to suppress the reflection of the incident light from the interface between the silicon oxynitride film SON1 and the fourth interlayer insulation film LIL.

Further, in the pixel region PER of the above-mentioned imaging device, it is possible to suppress the reflection of the incident light from an interface between the flattening film FF1 and the passivation film PSF. Description will be made with respect to this point.

The refractive index n of the silicon nitride film SN2 is about 1.9. The refractive index n of the flattening film FF1 that is made of the organic material such as resin and so forth is about 1.4 to about 1.5. The refractive index n of the silicon oxynitride film SON2 is about 1.5 to about 1.7. The silicon oxynitride film SON2 is interposed between the flattening film FF1 and the silicon nitride film SN2 in the pixel region PER.

Thereby, the difference between the refractive index of the flattening film FF1 and the refractive index of the silicon oxynitride film SON2 (the passivation film PSF) becomes smaller than the difference between the refractive index of the flattening film FF1 and the refractive index of the silicon nitride film SN2. Consequently, it is possible to suppress the reflection of the incident light from the interface between the flattening film FF1 and the silicon oxynitride film SON2 (the passivation film PSF) .

In the above-mentioned imaging device, it is possible to suppress the reflection of the incident light from the interface between the flattening film FF1 and the passivation film PSF and the interface between the passivation film PSF and the fourth interlayer insulation film LIL and it is possible to further improve the sensitivity of the imaging device in this way.

### Fourth Embodiment

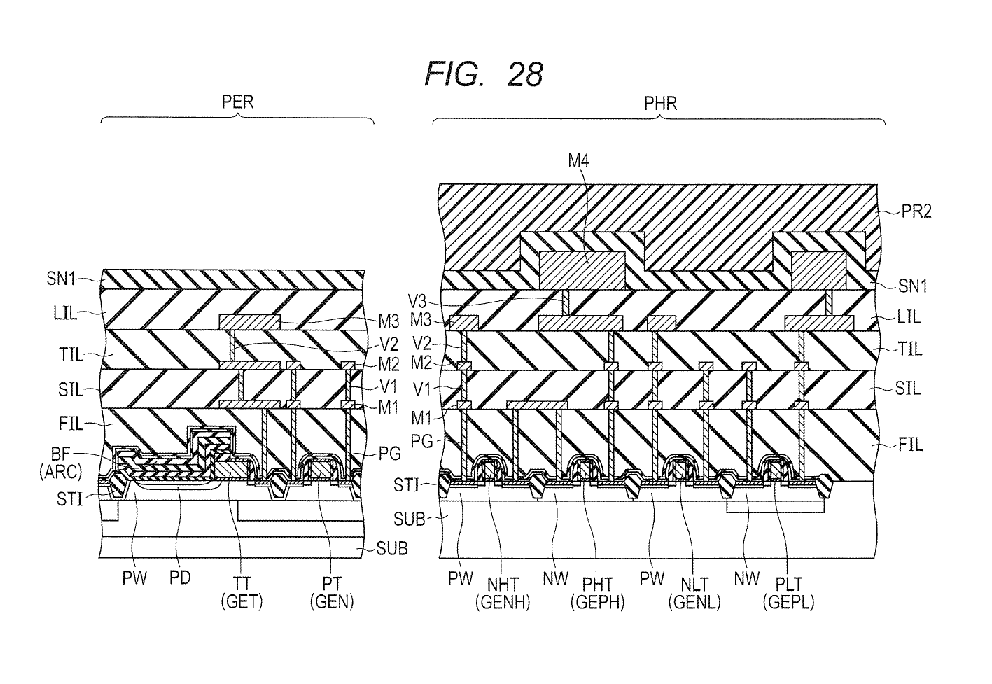

An imaging device according to the fourth embodiment will be described. First, one example of a manufacturing method for the imaging device will be described. First, as illustrated in FIG. 28, the silicon nitride film SN1 is exposed in the pixel region PER and the photoresist pattern PR2 that covers the silicon nitride film SN1 is formed in the peripheral circuit region PHR through the same processes as the processes illustrated in FIG. 4 to FIG. 12.

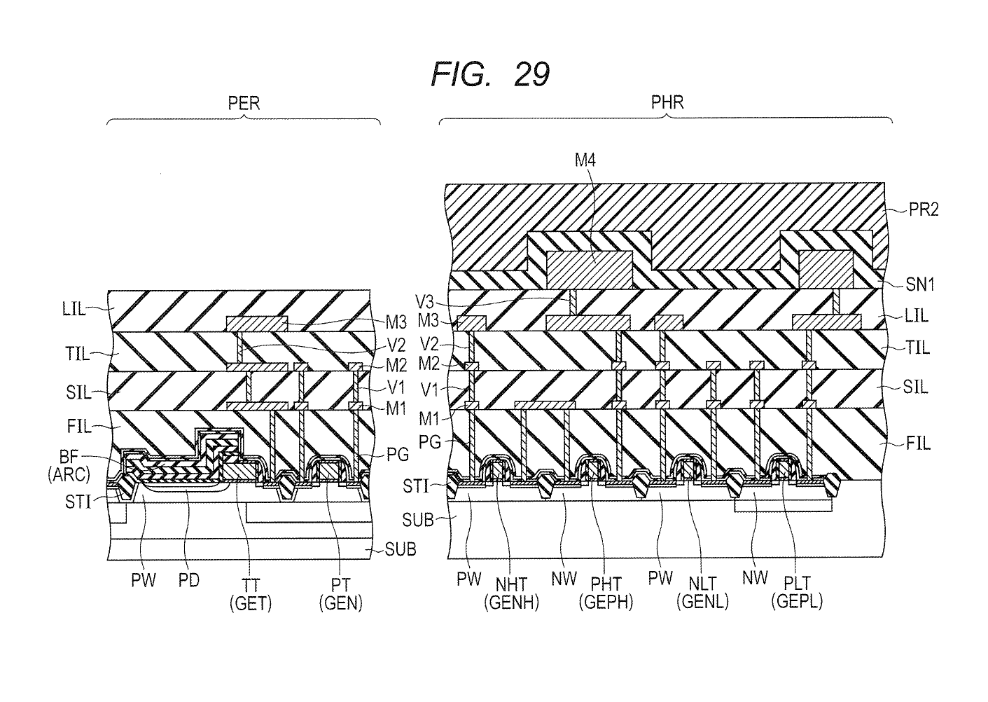

Then, as illustrated in FIG. 29, the silicon nitride film SN1 that is exposed to the outside in the pixel region PER is removed by performing the etching process by using the photoresist pattern PR2 as the etching mask and thereby the surface of the fourth interlayer insulation film LIL is exposed to the outside. The exposed fourth interlayer insulation film LIL is etched by further continuously performing the etching process.

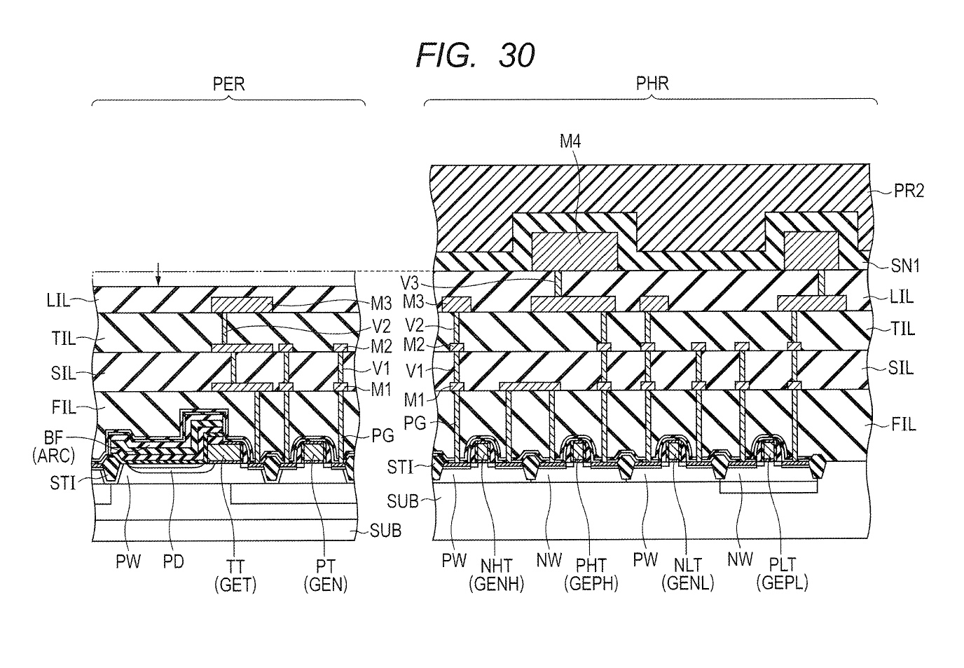

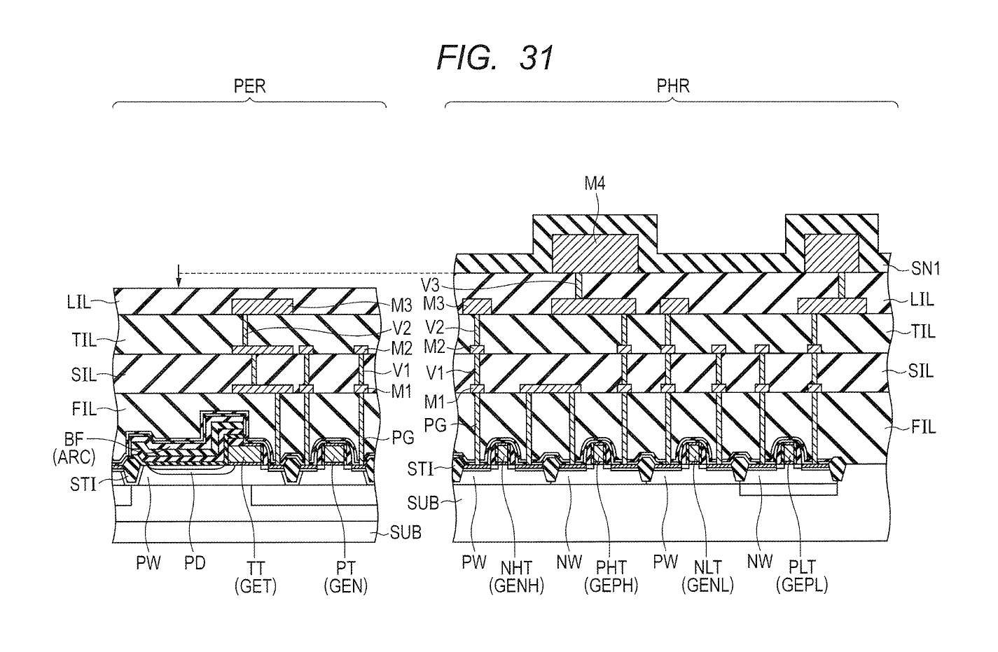

Thereby, as illustrated in FIG. 30, the surface of the fourth interlayer insulation film Lil that is situated in the pixel region PER is situated at a position lower than that of the surface of the fourth interlayer insulation film LIL that is situated in the peripheral circuit region PHR. Thereafter, as illustrated in FIG. 31, the photoresist pattern PR2 is removed and the silicon nitride film SN1 that is situated in the peripheral circuit region PHR is exposed to the outside.

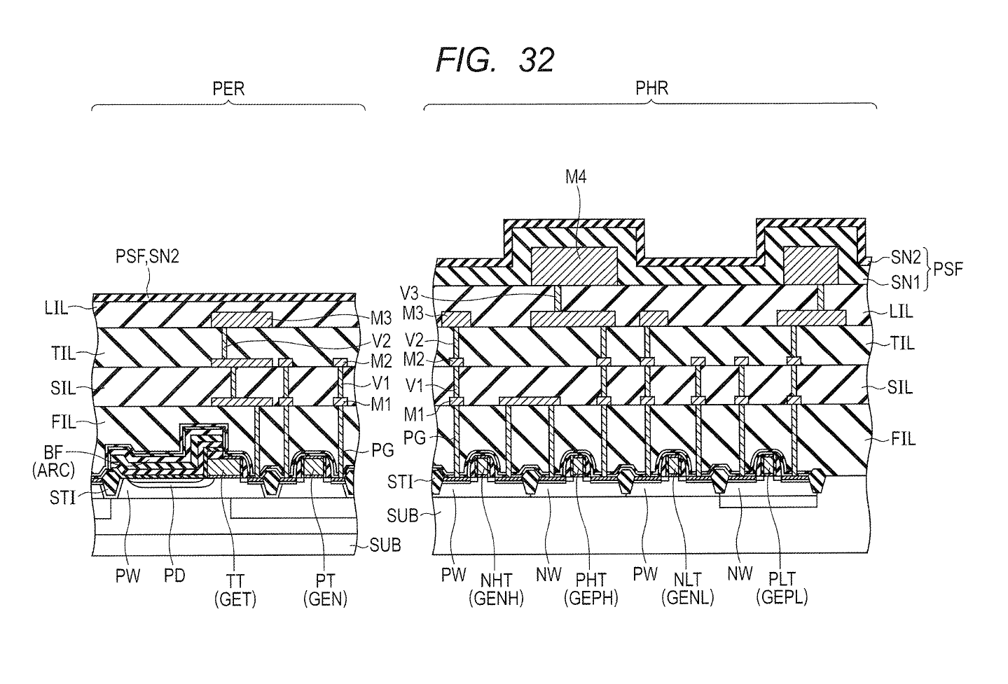

Then, as illustrated in FIG. 32, the silicon nitride film SN2 that is about 200 nm to about 300 nm film thickness is formed by, for example, the plasma CVD method. The silicon nitride film SN2 is formed so as to cover the fourth interlayer insulation film LIL in the pixel region PER. The silicon nitride film SN2 is formed so as to cover the silicon nitride film SN1 in the peripheral circuit region PHR.

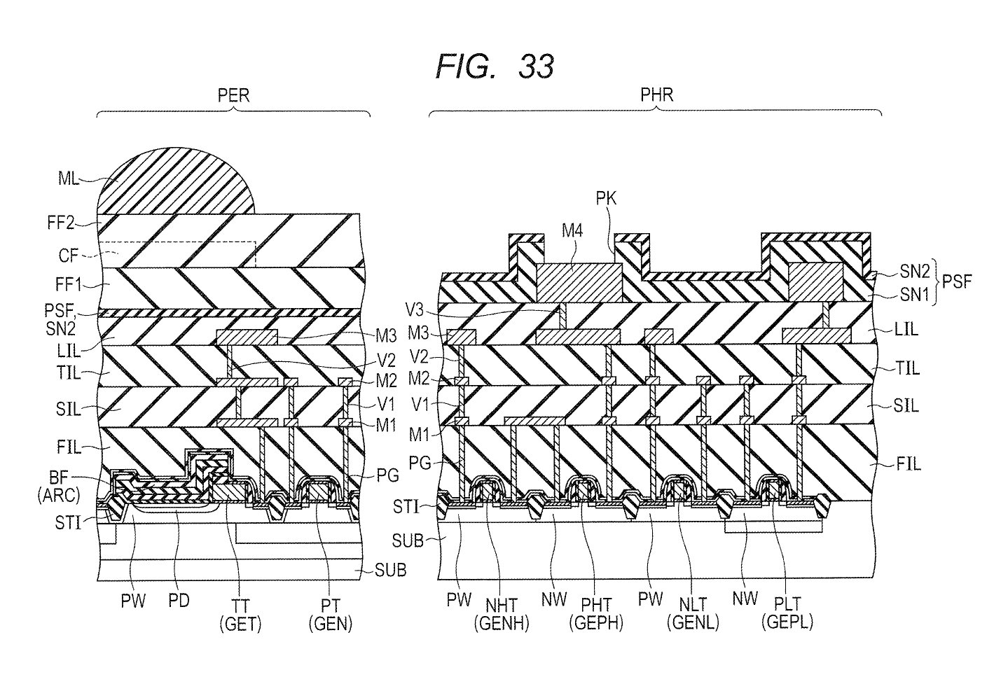

The passivation film PSF that includes the silicon nitride film SN2 and so forth is formed in the pixel region PER in this way. The passivation film PSF that the silicon nitride film SN1 and the silicon nitride film SN2 are laminated is formed in the peripheral circuit region PHR. Thereafter, formation of the principal parts of the imaging device is completed through the same processes as the processes illustrated in FIG. 14 to FIG. 19 as illustrated in FIG. 33.

In the above-mentioned imaging device, the passivation film PSF that is situated in the peripheral circuit region PHR is formed with the film thickness that is thicker than the film thickness of the passivation film PSF that is situated in the pixel region PER and thereby it is possible to sufficiently ensure the humidity resistance of the imaging device similarly to the configuration described in the first embodiment.

Further, in the above-mentioned imaging device, the surface of the fourth interlayer insulation film LIL in the pixel region PER is situated at the position lower than that of the surface of the fourth interlayer insulation film LIL in the peripheral circuit region PHR. Therefore, an interface (an interface A) between the fourth interlayer insulation film LIL and the passivation film PSF in the pixel region PER is situated at a position lower than that of an interface (an interface B) between the fourth interlayer insulation film LIL and the passivation film PSF in the peripheral circuit region PHR.

Thereby, a distance between the microlens ML upon which light is incident and the photodiode PD becomes shorter (lower in profile) than a distance obtained when the interface A is at the same level (position) as the interface B. Consequently, it is possible to further suppress the attenuation of the incident light and it is possible to surely suppress a reduction in sensitivity of the imaging device.

### Fifth Embodiment

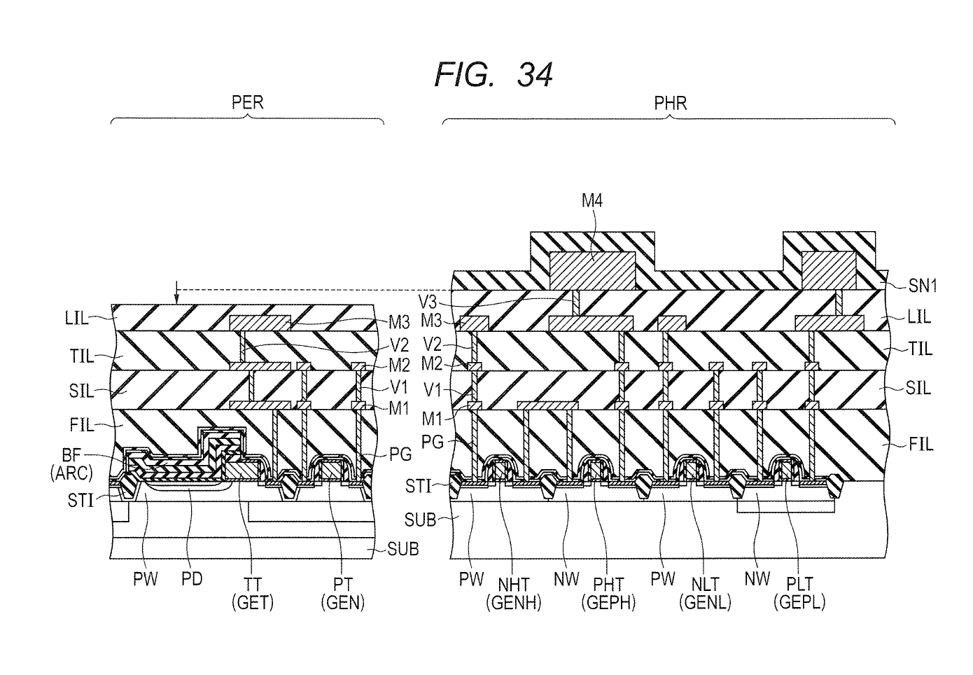

An imaging device according to the fifth embodiment will be described. First, one example of a manufacturing method for the imaging device will be described. First, after the same processes as the processes illustrated in FIG. 4 to FIG. 11 have been performed and then the same processes as the processes in FIG. 30 and FIG. 31 have been performed, the surface of the fourth interlayer insulation film LIL that is situated in the pixel region PER is situated at a position lower than that of the surface of the fourth interlayer insulation film LIL that is situated in the peripheral circuit region PHR and the silicon nitride film SN1 that is situated in the peripheral circuit region PHR is exposed to the outside as illustrated in FIG. 34.

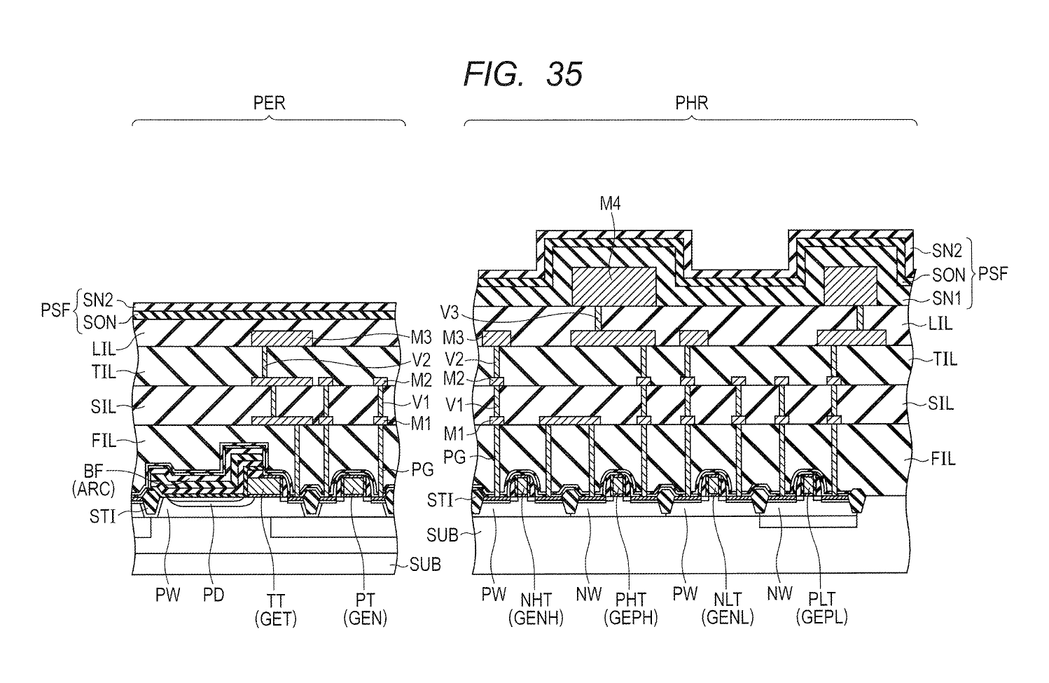

Then, as illustrated in FIG. 35, the silicon oxynitride film SON that is about 50 nm to about 80 nm in film thickness is formed by, for example, the plasma CVD method. Then, the silicon nitride film SN2 that is about 200 nm to about 300 nm in film thickness is formed by, for example, the plasma CVD method.

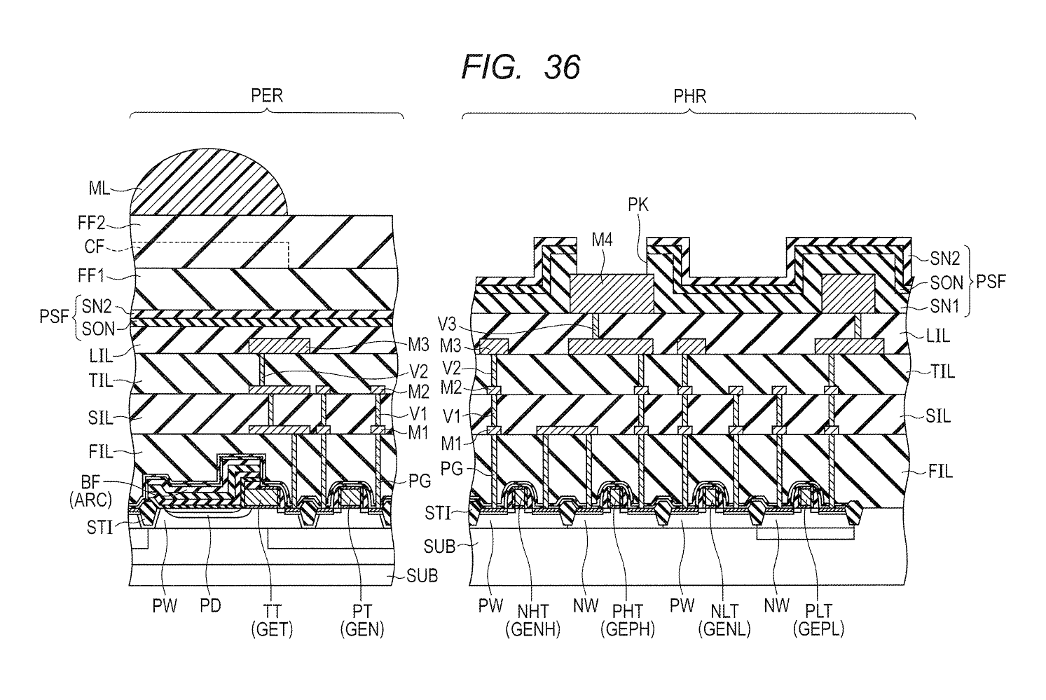

The passivation film PSF that the silicon nitride film SN2 is laminated over the silicon oxynitride film SON is formed in the pixel region PER in this way. The passivation film PSF that the silicon nitride film SN1, the silicon oxynitride film SON and the silicon nitride film SN2 are laminated is formed in the peripheral circuit region PHR. Thereafter, formation of the principal parts of the imaging device is completed through the same processes as the processes illustrated in FIG. 14 to FIG. 19 as illustrated in FIG. 36.

In the above-mentioned imaging device, the passivation film PSF that is situated in the peripheral circuit region PHR is formed with the film thickness that is thicker than the film thickness of the passivation film PSF that is situated in the pixel region similarly to the configuration described in the second embodiment and thereby it is possible to sufficiently ensure the humidity resistance of the imaging device.

In addition, the silicon oxynitride film SON (the refractive index n: about 1.5 to about 1.7) is interposed between the fourth interlayer insulation film LIL (the refractive index n: about 1.4 to about 1.5) and the silicon nitride film SN2 (the refractive index n: about 1.9) in the pixel region PER similarly to the configuration described in the second embodiment. Thereby, it is possible to suppress the reflection of the incident light from the interface between the silicon oxynitride film SON (the passivation film PSF) and the fourth interlayer insulation film LIL.

Further, in the above-mentioned imaging device, the interface (the interface A) between the fourth interlayer insulation film LIL and the passivation film PSF in the pixel region PER is situated at the position lower than that of the interface (the interface B) between the fourth interlayer insulation film LIL and the passivation film PSF in the peripheral circuit region PHR similarly to the configuration described in the fourth embodiment.

Thereby, the distance between the microlens ML upon which light is incident and the photodiode PD becomes shorter (lower in profile) than the distance obtained when the interface A is at the same level (position) as the interface B. Consequently, it is possible to further suppress the attenuation of the incident light and it is possible to surely suppress the reduction in sensitivity of the imaging device.

### Sixth Embodiment

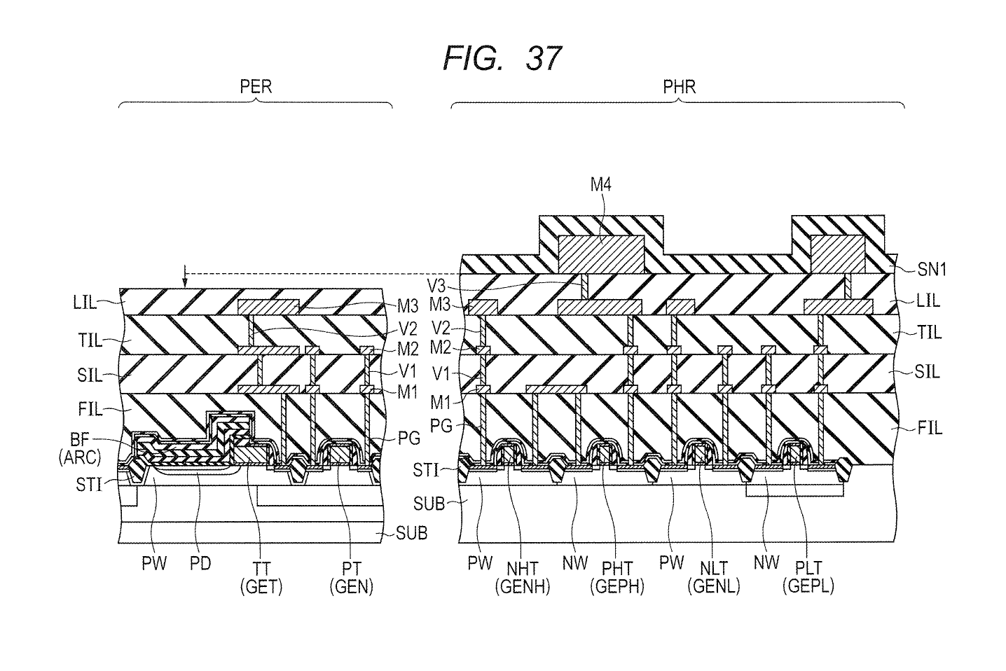

An imaging device according to the sixth embodiment will be described. First, one example of a manufacturing method for the imaging device will be described. First, after the same processes as the processes illustrated in FIG. 4 to FIG. 11 have been performed and then the same processes as the processes in FIG. 30 and FIG. 31 have been performed, as illustrated in FIG. 37, the surface of the fourth interlayer insulation film LIL that is situated in the pixel region PER is situated at the position lower than that the surface of the fourth interlayer insulation film LIL that is situated in the peripheral circuit region PHR and the silicon nitride film SN1 that is situated in the peripheral circuit region PHR is exposed to the outside.

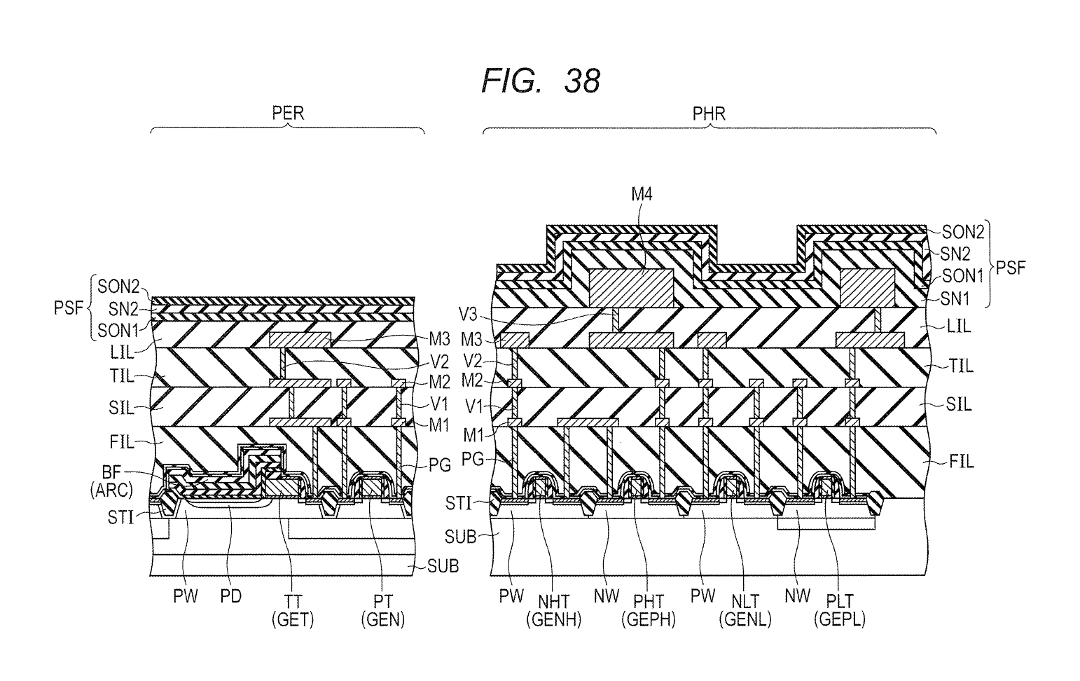

Then, as illustrated in FIG. 38, the silicon oxynitride film SON1 that is about 50 nm to about 80 nm in film thickness is formed by, for example, the plasma CVD method. Then, the silicon nitride film SN2 that is about 200 nm to about 300 nm in film thickness is formed by, for example, the plasma CVD method. Then, the silicon oxynitride film SON2 that is about 50 nm to about 80 nm in film thickness is further formed by, for example, the plasma CVD method.

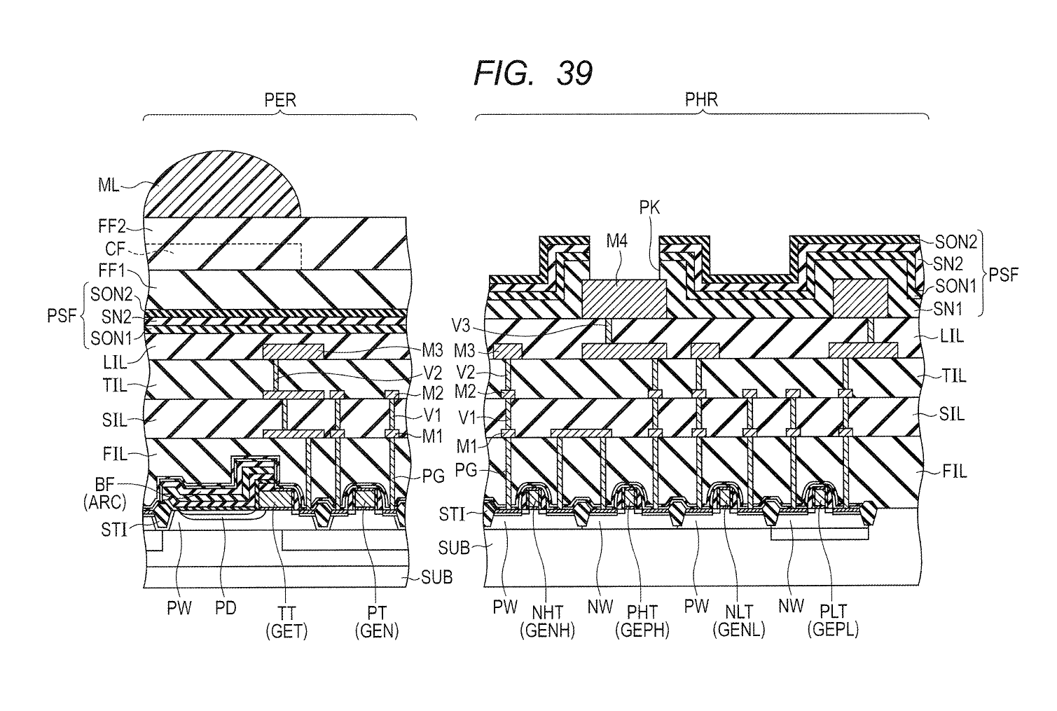

The passivation film PSF that the silicon oxynitride film SON1, the silicon nitride film SN2 and the silicon oxynitride film SON2 are laminated is formed in the pixel region PER in this way. The passivation film PSF that the silicon nitride film SN1, the silicon oxynitride film SON1, the silicon nitride film SN2 and the silicon oxynitride film SON2 are laminated is formed in the peripheral circuit region PHR. Thereafter, formation of the principal parts of the imaging device is completed through the same processes as the processes illustrated in FIG. 14 to FIG. 19 as illustrated in FIG. 39.

In the above-mentioned imaging device, the passivation film PSF that is situated in the peripheral circuit region PHR is formed with the film thickness that is thicker than the film thickness of the passivation film PSF that is situated in the pixel region similarly to the configuration described in the third embodiment and thereby it is possible to sufficiently ensure the humidity resistance of the imaging device.

In addition, the silicon oxynitride film SON1 (the refractive index n: about 1.5 to about 1.7) is interposed between the fourth interlayer insulation film LIL (the refractive index n: about 1.4 to about 1.5) and the silicon nitride film SN2 (the refractive index n: about 1.9) in the pixel region PER similarly to the configuration described in the third embodiment. Then, the silicon oxynitride film SON2 (the refractive index n: about 1.5 to about 1.7) is interposed between the flattening film FF1 (the refractive index n: about 1.4 to about 1.5) and the silicon nitride film SN2 (the refractive index n: about 1.9).

Thereby, it is possible to suppress the reflection of the incident light from the interface between the flattening film FF1 and the silicon oxynitride film SON2 (the passivation film PSF) and it is also possible to suppress the refection of the incident light from the interface between the silicon oxynitride film SON1 and the fourth interlayer insulation film LIL.

Further, in the above-mentioned imaging device, the interface (the interface A) between the fourth interlayer insulation film LIL and the passivation film PSF in the pixel region PER is situated at the position lower than that of the interface (the interface B) between the fourth interlayer insulation film LIL and the passivation film PSF in the peripheral circuit region PHR similarly to the configuration described in the fourth embodiment.

Thereby, the distance between the microlens ML upon which light is incident and the photodiode PD becomes shorter (lower in profile) than the distance obtained when the interface A is at the same level (position) as the interface B. Consequently, it is possible to further suppress the attenuation of the incident light and it is possible to surely suppress the reduction in sensitivity of the imaging device.

### Seventh Embodiment

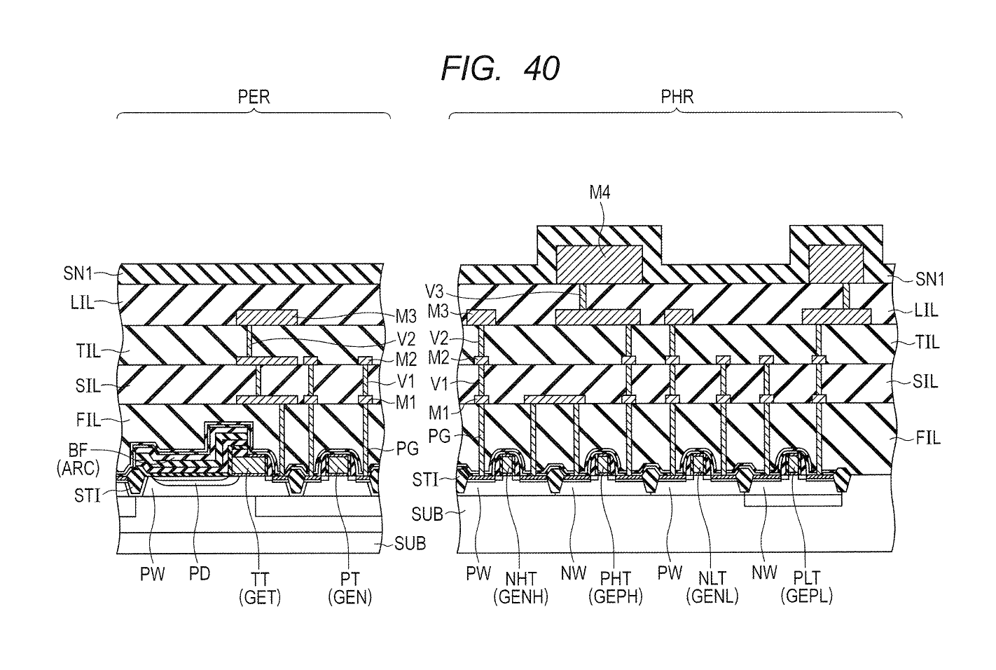

An imaging device according to the seventh embodiment will be described. First, one example of a manufacturing method for the imaging device will be described. First, as illustrated in FIG. 40, the silicon nitride film SN1 that is about 700 nm to about 800 nm in film thickness is formed so as to cover the fourth interlayer insulation film LIL through the same processes as the processes illustrated in FIG. 4 to FIG. 10.

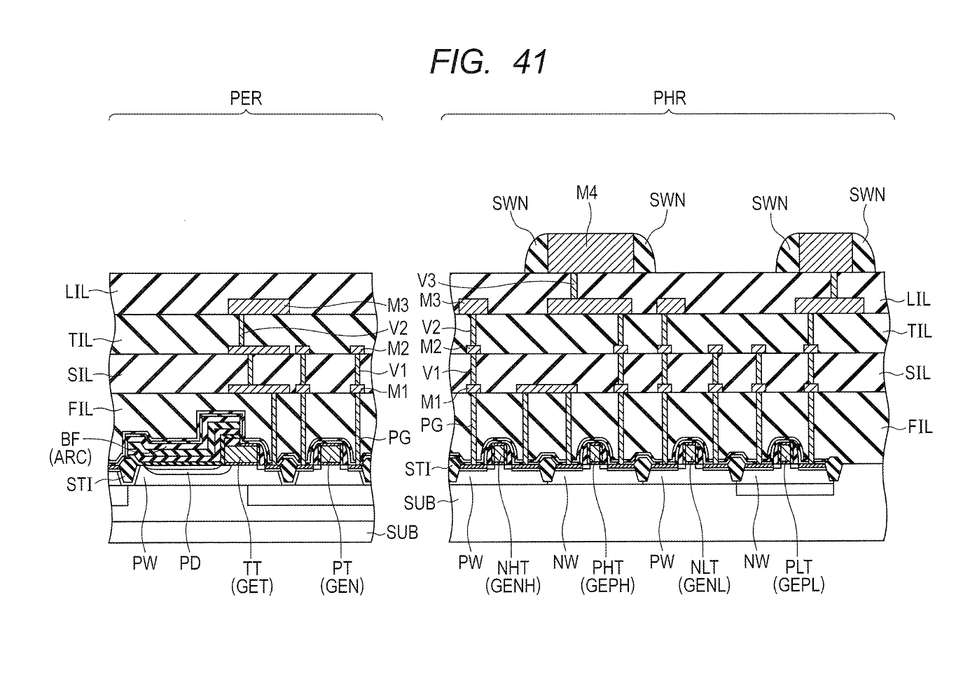

Then, as illustrated in FIG. 41, an anisotropic etching process is performed on the entire surface of the silicon nitride film SN1 and thereby a part of the silicon nitride film SN1 that is situated on each side face of each fourth wiring layer M4 is left as it is and a part of the silicon nitride film SN1 that is situated over the upper surface of the fourth interlayer insulation film LIL is removed. Thereby, a side wall nitride film SW is formed on each side face of each fourth wiring layer M4 in the peripheral circuit region PHR.

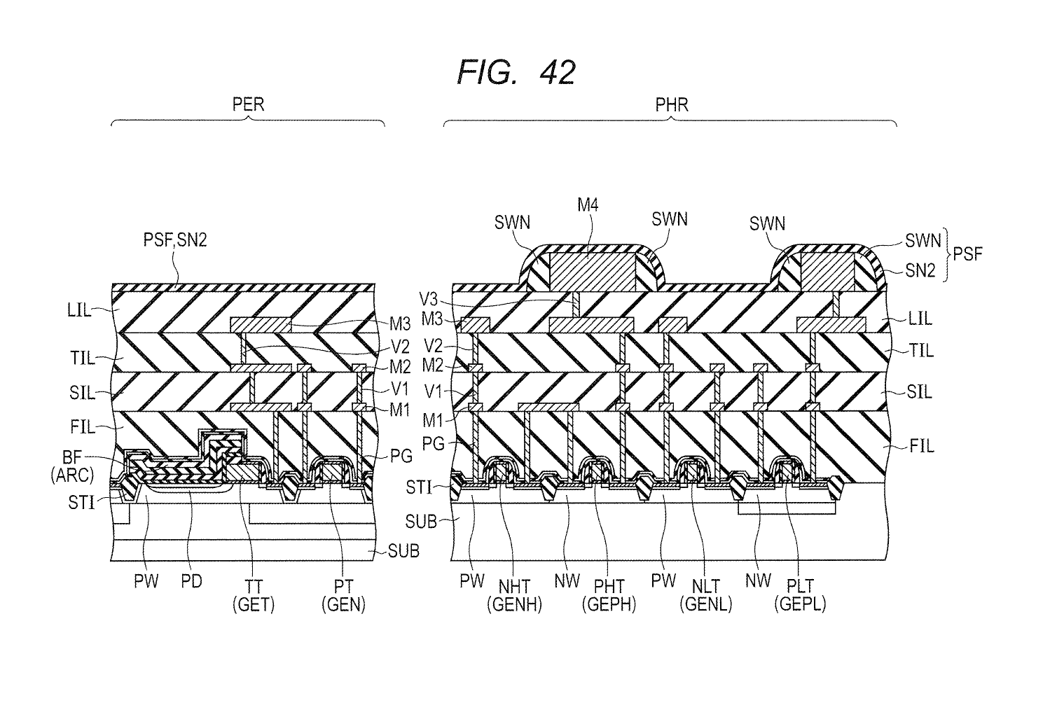

Then, as illustrated in FIG. 42, the silicon nitride film SN2 that is about 200 nm to about 300 nm in film thickness is formed by, for example, the plasma CVD method. The silicon nitride film SN2 is formed so as to cover the fourth interlayer insulation film LIL in the pixel region PER. The silicon nitride film SN2 is formed so as to cover the side wall nitride films SWN and the fourth wiring layers M4 in the peripheral circuit region PHR.

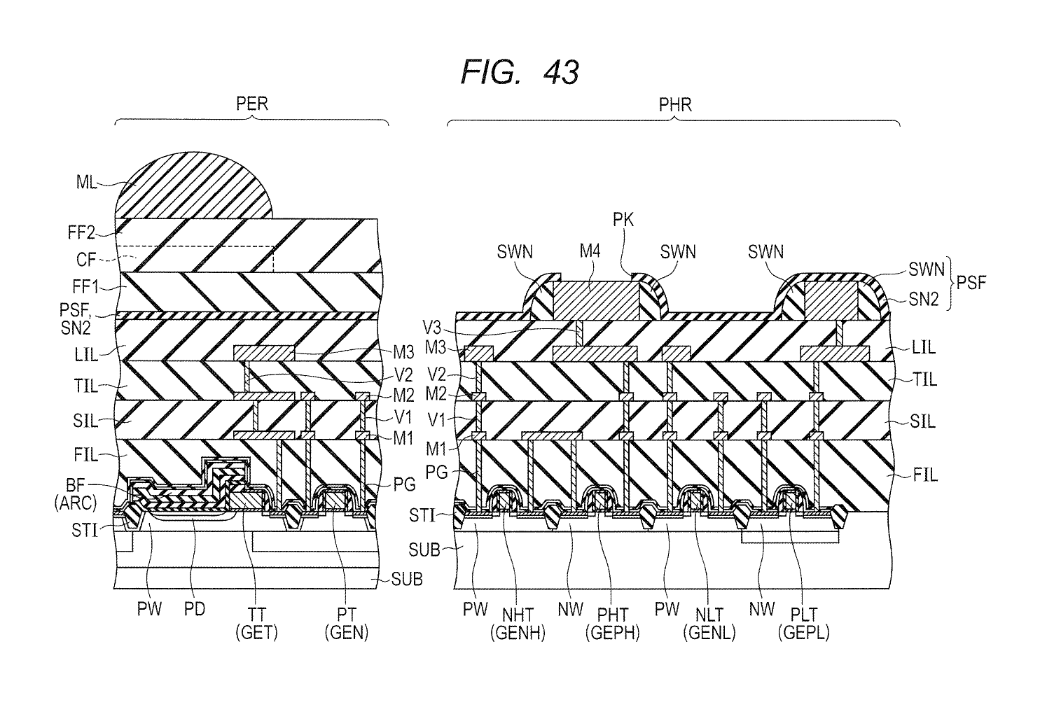

The passivation film PSF that includes the silicon nitride film SN2 and so forth is formed in the pixel region PER in this way. The passivation film PSF that includes the side wall nitride films SWN, the silicon nitride film SN2 and so forth is formed in the peripheral circuit region PHR. Thereafter, as illustrated in FIG. 43, formation of the principal parts of the imaging device is completed through the same processes as the processes illustrated in FIG. 14 to FIG. 19.

In the peripheral circuit region PHR of the above-mentioned imaging device, the side wall nitride films SWN are formed so as to cover the side faces of the respective fourth wiring layers M4 and further the silicon nitride film SN2 is formed so as to cover the side wall nitride films SWN and the fourth wiring layers M4. Thereby, it is possible to sufficiently ensure the humidity resistance of the imaging device and it is possible to improve the reliability of the imaging device.

Moreover, since the side wall nitride films SWN that cover the side faces of the respective fourth wiring layers M4 may be formed simply by performing an anisotropic etching process on the entire surface of the silicon nitride film and it is not requested to perform the photoengraving process, it is also possible to suppress an increase in production cost.

In addition, the comparatively thin passivation film PSF (the silicon nitride film SN2) is formed in the pixel region PER similarly to the configuration described in the first embodiment and thereby it is possible to suppress the attenuation of the incident light and it is possible to suppress the reduction in sensitivity of the imaging device.

Incidentally, the configurations of the imaging devices described in the respective embodiments may be mutually combined in a variety of ways as requested. In addition, although in the imaging device according to each embodiment, as for the number of the wiring layers to be arranged, description has been made by taking a case where three wiring layers are arranged in the pixel region PER and four wiring layers are arranged in the peripheral circuit region PHR by way of example, the above-mentioned number of the wiring layers is merely one example and the number of the wiring layers is not limited thereto. The number of the wiring layers to be arranged in the peripheral circuit region PHR may be the same as or larger than the number of the wiring layers to be arranged in the pixel region PER.

Although in the foregoing, the invention that has been made by the inventors and others has been specifically described on the basis of the preferred embodiments of the present invention, it goes without saying that the present invention is not limited to the above-mentioned embodiments and may be altered and modified in a variety of ways within the range not deviating from the gist of the present invention.

A seventh embodiment includes the following constitutional elements.

### [Appendix 1]

An imaging device includes

a semiconductor substrate,

a pixel region and a peripheral circuit region that are respectively defined on the semiconductor substrate,

a pixel element that is formed in the pixel region and includes a photoelectric conversion unit,

a peripheral circuit element that is formed in the peripheral circuit region,

a multilayered wiring structure that is formed so as to cover the pixel element and the peripheral circuit element and includes a plurality of wiring layers and a plurality of interlayer insulation films,

a color filter that is formed in the pixel region so as to cover the multilayered wiring structure,

a microlens that is formed over the color filter,

an interposition film that is interposed between an uppermost layer insulation film that is situated at the uppermost position in the plurality of interlayer insulation films and the color filter and extends from the pixel region to the peripheral circuit region in contact with the uppermost insulation film, and

peripheral wiring layers that are formed over the surface of the uppermost insulation film that is situated in the peripheral circuit region, in which

in the peripheral circuit region, the interposition film includes

a first part that is formed on each side face of each peripheral wiring layer, and

a second part that extends from the pixel region and covers the first part and each peripheral wiring layer.

What is claimed is:

1. An imaging device, comprising:
a semiconductor substrate;
a pixel region and a peripheral circuit region that are respectively defined on the semiconductor substrate;
a pixel element that is formed in the pixel region and includes a photoelectric conversion unit;
a peripheral circuit element that is formed in the peripheral circuit region;
a multilayered wiring structure that is formed so as to cover the pixel element and the peripheral circuit element and includes a plurality of wiring layers and a plurality of interlayer insulation films;
a color filter that is formed in the pixel region so as to cover the multilayered wiring structure;
a microlens that is formed over the color filter; and
an interposition film that is interposed between an uppermost insulation film that is situated at the uppermost position in the interlayer insulation films and the color filter and extends from the pixel region to the peripheral circuit region in contact with the uppermost insulation film,
wherein in the pixel region, the interposition film is formed with a first film thickness, and
wherein in the peripheral circuit region, the interposition film is formed with a second film thickness that is thicker than the first film thickness.

2. The imaging device according to claim 1,
wherein the interposition film includes a silicon nitride film.

3. The imaging device according to claim 2,
wherein a position of an interface along which the uppermost insulation film and the interposition film are in contact with each other in the pixel region is located lower than a position of an interface along which the uppermost insulation film and the interposition film are in contact with each other in the peripheral circuit region.

4. The imaging device according to claim 2,
wherein the interposition film includes a first silicon oxynitride film that is formed between the silicon nitride film and the uppermost insulation film.

5. The imaging device according to claim 4
wherein a position of an interface along which the uppermost insulation film and the interposition film are in contact with each other in the pixel region is located lower than a position of an interface along which the uppermost insulation film and the interposition film are in contact with each other in the peripheral circuit region.

6. The imaging device according to claim 2
wherein the interposition film includes a second silicon oxynitride film that is formed between the silicon nitride film and the color filter.

7. The imaging device according to claim 6
wherein a position of an interface along which the uppermost insulation film and the interposition film are in contact with each other in the pixel region is located lower than a position of an interface along which the uppermost insulation film and the interposition film are in contact with each other in the peripheral circuit region.

8. The imaging device according to claim 1
wherein in the wiring layers, the number of peripheral circuit wiring layers that are formed in the peripheral circuit region is the same as the number of pixel wiring layers that are formed in the pixel region or larger than the number of the pixel wiring layers that are formed in the pixel region.

9. A manufacturing method for imaging device, comprising the steps of :
(a) respectively defining a pixel region and a peripheral circuit region on a semiconductor substrate;
(b) forming a pixel element that includes a photoelectric conversion unit in the pixel region;
(c) forming a peripheral circuit element in the peripheral circuit region;
(d) forming a multilayered wiring stricture that includes a plurality of wiring layers and a plurality of interlayer insulation films so as to cover the pixel element and the peripheral circuit element; and
(e) forming a color filter and a microlens over an uppermost insulation film that is situated at the uppermost position in the interlayer insulation films,
wherein the step of forming an interposition film that is interposed between the uppermost insulation film and the color filter and extends from the pixel region to the peripheral circuit region in contact with the uppermost insulation film is included between the step of forming the multilayered wiring structure and the step of forming the color filter and the microlens,
wherein the step of forming the interposition film includes the steps of
forming a first film,
leaving a part of the first film that is situated in the peripheral circuit region as it is, removing a part of the first film that is situated in the pixel region in the first film, and exposing the uppermost insulation film, and
forming a second film so as to cover the exposed uppermost insulation film in the pixel region and so as to cover the left part of the first film in the peripheral circuit region.

10. The manufacturing method for imaging device according to claim 9
wherein the step of forming the first film in the step of forming the interposition film includes the step of forming a first silicon nitride film, and
wherein the step of forming the second film in the step of forming the interposition film includes the step of forming a second silicon nitride film.

11. The manufacturing method for imaging device according to claim 10,
wherein the step of forming the uppermost insulation film in the step of forming the multilayered wiring structure includes the step of setting a surface of the uppermost insulation film situated in the pixel region at a position lower than that of a surface of the uppermost insulation film situated in the peripheral circuit region.

12. The manufacturing method for imaging device according to claim 9,
wherein the step of forming the first film in the step of forming the interposition film includes the step of forming a first silicon nitride film, and
wherein the step of forming the second film in the step of forming the interposition film includes the step of sequentially laminating a first silicon oxynitride film and a second silicon oxynitride film.

13. The manufacturing method for imaging device according to claim 12,
wherein the step of forming the uppermost insulation film in the step of forming the multilayered wiring structure includes the step of setting a surface of the uppermost insulation film situated in the pixel region at a position lower than that of a surface of the uppermost insulation film situated in the peripheral circuit region.

14. The manufacturing method for imaging device according to claim 9,
wherein the step of forming the first film in the step of forming the interposition film includes the step of forming a first silicon nitride film, and
wherein the step of forming the second film in the step of forming the interposition film includes the step of sequentially laminating a first silicon oxynitride film, a second silicon nitride film and a second silicon oxynitride film.

15. The manufacturing method for imaging device according to claim 14,
wherein the step of forming the uppermost insulation film in the step of forming the multilayered wiring structure includes the step of setting a surface of the uppermost insulation film situated in the pixel region at a position lower than that of a surface of the uppermost insulation film situated in the peripheral circuit region.

16. The manufacturing method for imaging device according to claim 9, further comprising the step of:
further forming peripheral wiring layers over the surface of the uppermost insulation film situated in the peripheral circuit region,
wherein the step of forming the first film in the step of forming the interposition film includes the steps of
forming the first film so as to cover the peripheral wiring layers, and
leaving side wall parts on side faces of the peripheral wiring layers as they are and removing other parts by performing an etching process on the first film, and
wherein the step of forming the second film in the step of forming the interposition film includes the step of forming the second film so as to cover the left side wall parts and the peripheral wiring layers in the peripheral circuit region.
